(19) United States
(12) Patent Application Publication
(10) Pub. No.: US 2024/0357793 A1
(43) Pub. Date: Oct. 24, 2024

(54) MICROELECTRONIC DEVICES AND MEMORY DEVICES INCLUDING VERTICALLY SPACED TRANSISTORS AND STORAGE DEVICES, AND RELATED ELECTRONIC SYSTEMS

(71) Applicant: Micron Technology, Inc., Boise, ID (US)

(72) Inventor: Fatma Arzum Simsek-Ege, Boise, ID (US)

(21) Appl. No.: 18/619,425

(22) Filed: Mar. 28, 2024

Related U.S. Application Data
(60) Provisional application No. 63/496,790, filed on Apr. 18, 2023.

(51) Int. Cl. H10B 12/00

(52) U.S. Cl. CPC H10B 12/00

(57) ABSTRACT

A microelectronic device comprises a first transistor structure, a second transistor structure vertically overlying the first transistor structure, a storage device vertically overlying the second transistor structure, a first conductive contact structure contacting the first transistor structure, the second transistor structure, and a first electrode of the storage device, and a second conductive contact structure configured to be in electrical communication with the first transistor structure and the second transistor structure. Related memory devices and electronic systems are also described.

### CROSS-REFERENCE TO RELATED APPLICATION

This application claims the benefit under 35 U.S.C. § 119 (e) of U.S. Provisional Patent Application Ser. No. 63/496,790, filed Apr. 18, 2023, the disclosure of which is hereby incorporated herein in its entirety by this reference.

### TECHNICAL FIELD

The disclosure, in various embodiments, relates generally to the field of microelectronic device design and fabrication. More specifically, the disclosure relates to microelectronic devices including memory cells individually comprising vertically spaced transistors and storage devices, and to related memory devices and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often seek to design architectures that are not only compact, but offer performance advantages, as well as simplified designs.

One example of a semiconductor device is a memory device. Memory devices are generally provided as internal integrated circuits in computers or other electronic devices. There are many types of memory including, but not limited to, random-access memory (RAM), read only memory (ROM), dynamic random access memory (DRAM), synchronous dynamic random access memory (SDRAM), flash memory, and resistance variable memory. Non-limiting examples of resistance variable memory include resistive random access memory (RRAM), conductive bridge random access memory (conductive bridge RAM), magnetic random access memory (MRAM), phase change material (PCM) memory, phase change random access memory (PCRAM), spin-torque-transfer random access memory (STTRAM), oxygen vacancy-based memory, and programmable conductor memory.

A typical memory cell of a memory device includes one access device, such as a transistor, and one memory storage structure, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines (e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D) so as to exhibit multiple decks (e.g., multiple levels, multiple tiers) of the memory cells.

To improve the operating parameters of the memory cell, some have formed so-called two transistor-one capacitor memory cells wherein the storage device is in communication with two transistors, and some have desired to increase the capacitance of the storage device. However, increasing the number of transistors for each memory cell undesirably increases the area occupied by the memory cells and decreases the packing density of the memory cells of the array. In addition, increasing the capacitance of the storage device increases the area occupied by the memory cell.

### BRIEF DESCRIPTION OF THE DRAWINGS

FIG. 1A through FIG. 1Y are simplified, partial top-down view (FIG. 1A,

FIG. 1G, FIG. 1K, FIG. 1N, FIG. 1Q, FIG. 1S, and FIG. 1W) and simplified, partial cross-sectional views (FIG. 1B through FIG. 1F, FIG. 1H, FIG. 1K through FIG. 1M, FIG. 1P,

FIG. 1R, FIG. 1T through FIG. 1V, FIG. 1X, and FIG. 1Y) illustrating a method of forming a microelectronic device, in accordance with embodiments of the disclosure;

FIG. 2A and FIG. 2B are simplified, partial cross-sectional views of a microelectronic device, in accordance with embodiments of the disclosure; and

FIG. 3 is a block diagram of an electronic system, in accordance with embodiments of the disclosure.

### DETAILED DESCRIPTION

The illustrations included herewith are not meant to be actual views of any particular systems, microelectronic structures, microelectronic devices, or integrated circuits thereof, but are merely idealized representations that are employed to describe embodiments herein. Elements and features common between figures may retain the same numerical designation except that, for ease of following the description, reference numerals begin with the number of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device, such as DRAM memory device), apparatus, memory device, or electronic system, or a complete microelectronic device, apparatus, memory device, or electronic system including conductive contact structures. The structures described below do not form a complete microelectronic device, apparatus, memory device, or electronic system. Only those process acts and structures necessary to understand the embodiments described herein are described in detail below. Additional acts to form a complete microelectronic device, apparatus, memory device, or electronic system from the structures may be performed by conventional techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including an insulative material.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth.

According to embodiments described herein, an array of memory cells includes memory cells, each individually comprising two transistors and one storage device (e.g., two transistor-one capacitor (2T-1C)) memory cells. The memory cells may individually comprise the storage device vertically spaced from the transistors. The transistors may be vertically spaced from one another. In some such embodiments, a second vertical transistor of a memory cell may be located within the horizontal boundaries of a first vertical transistor of the memory cell. The first transistor and the second transistor may be in electrical communication with an electrode of the storage device. The storage device may vertically overlie the transistors and may include multiple levels of electrode materials and dielectric materials. The multiple levels of the electrode materials and dielectric materials may facilitate increasing the capacitance of the storage device compared to storage devices formed within a single vertical plane.

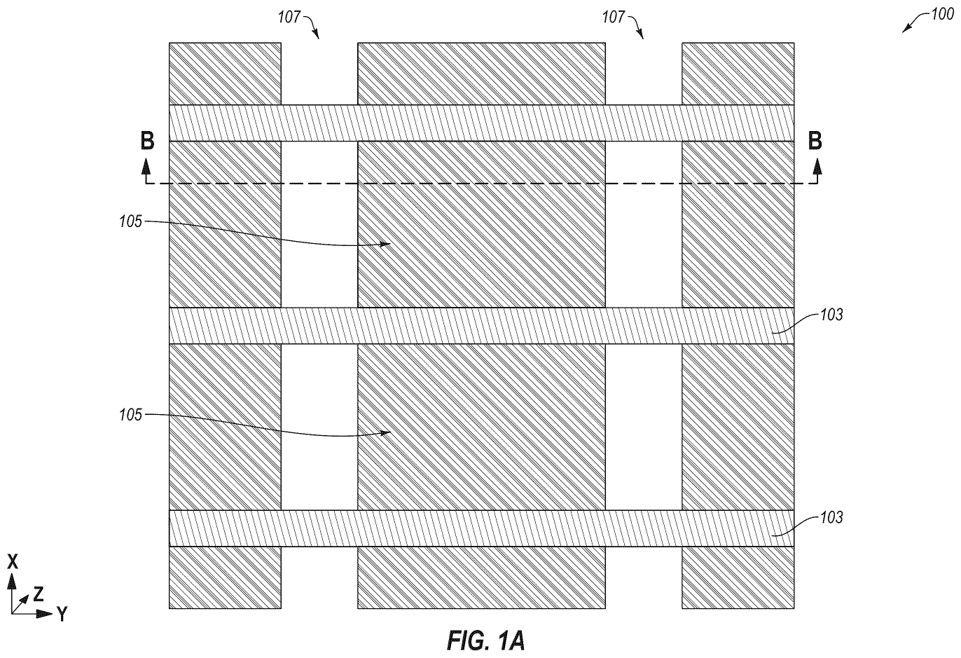

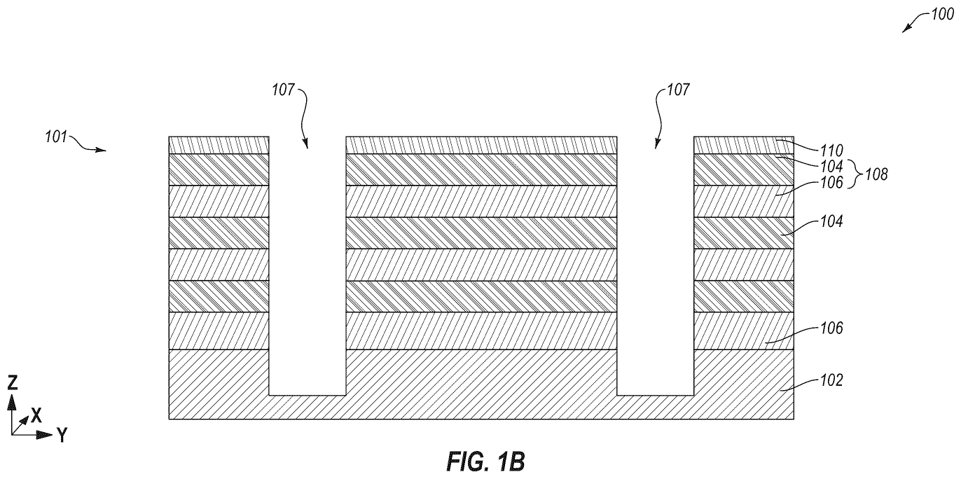

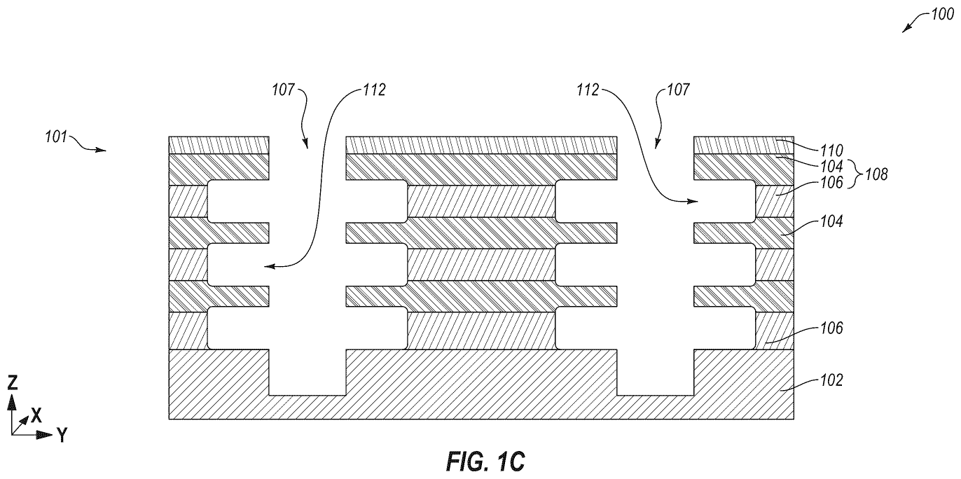

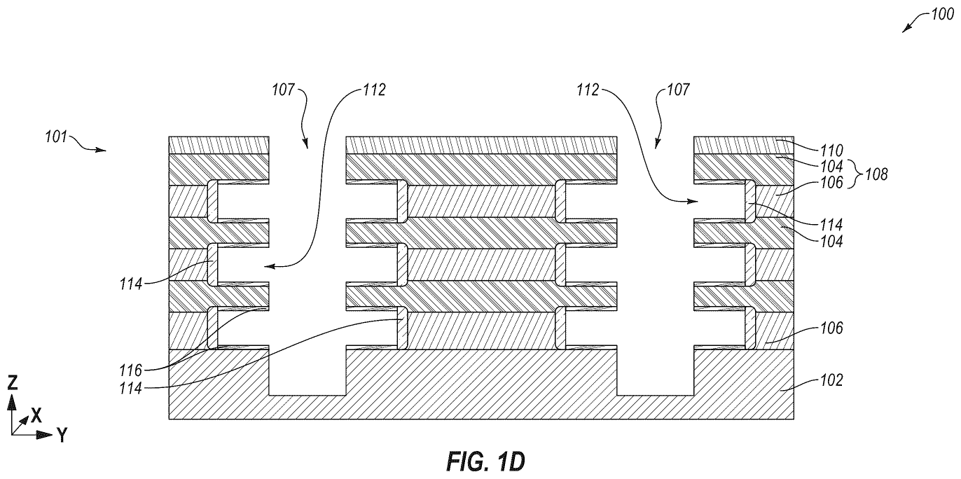

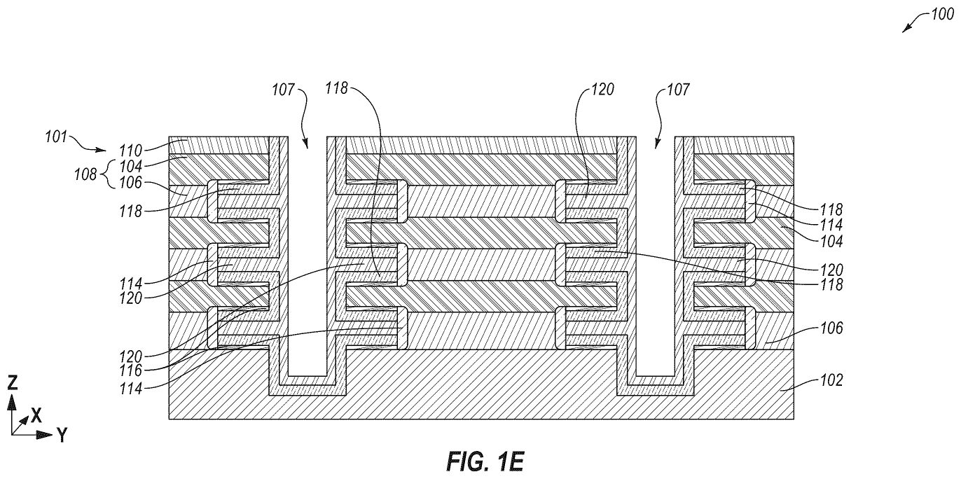

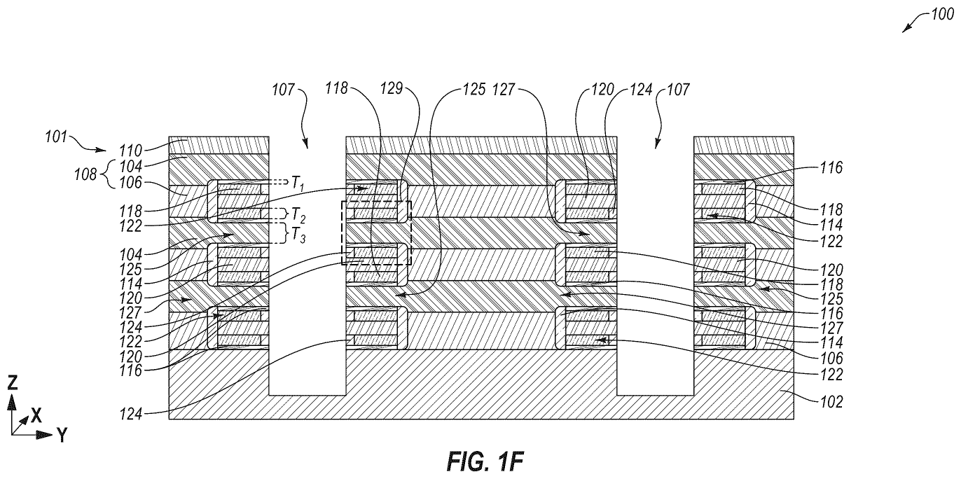

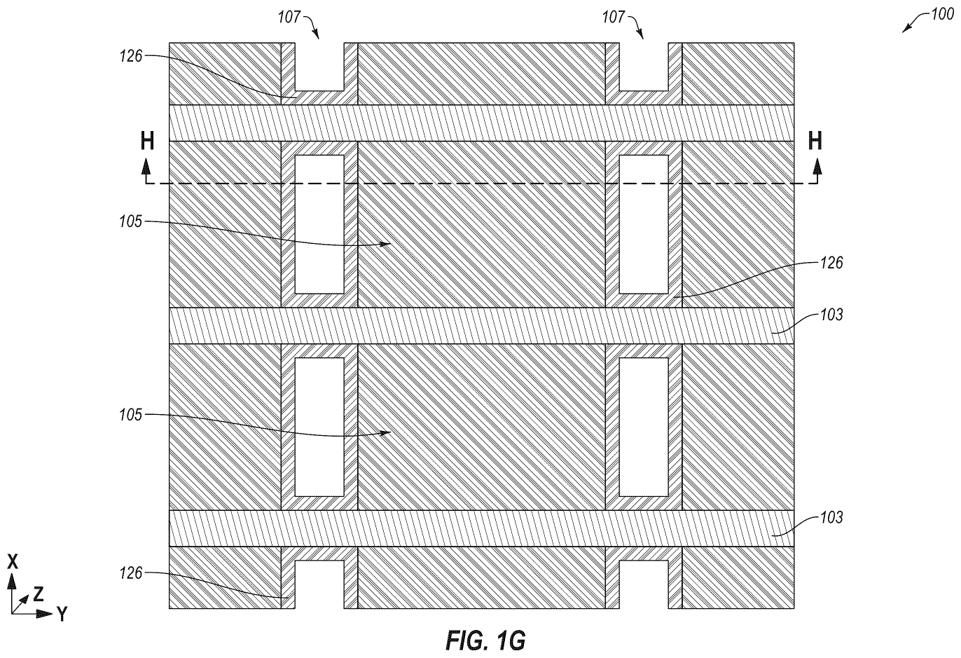

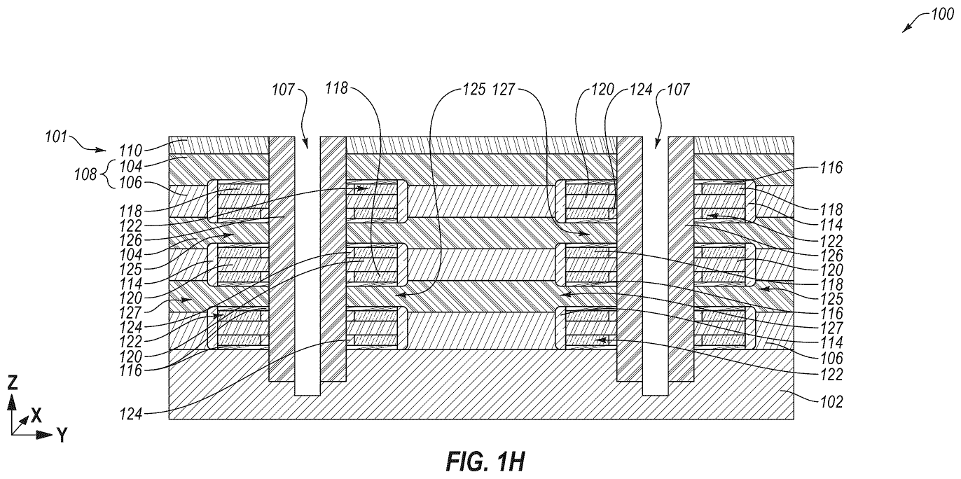

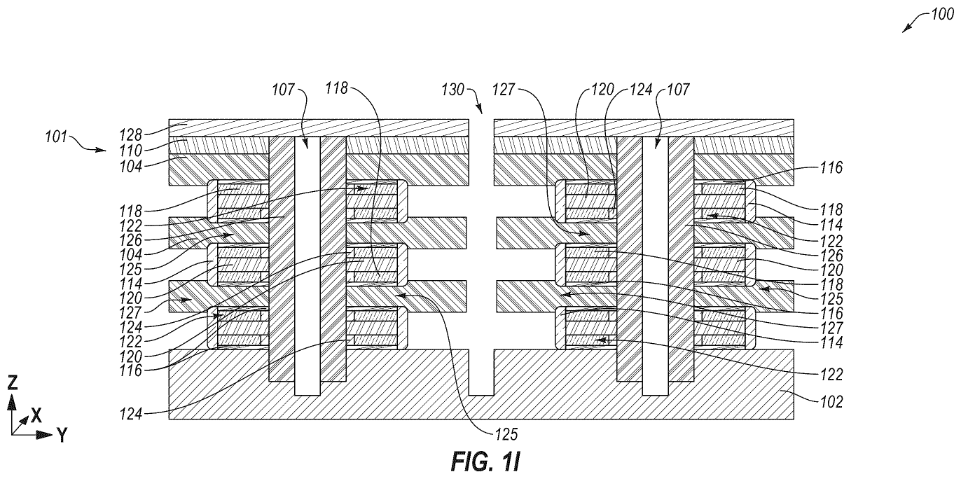

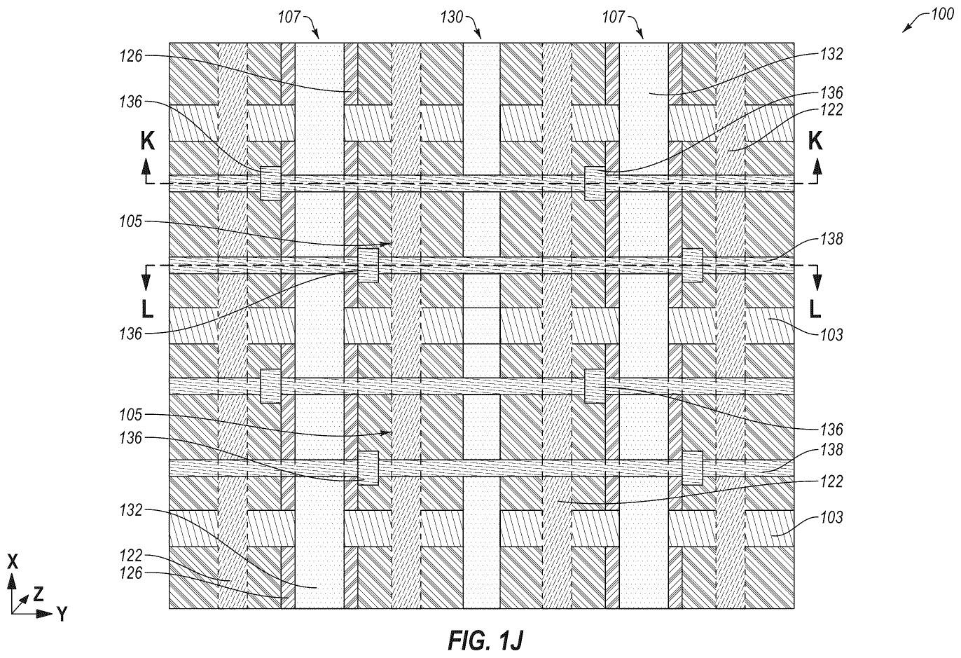

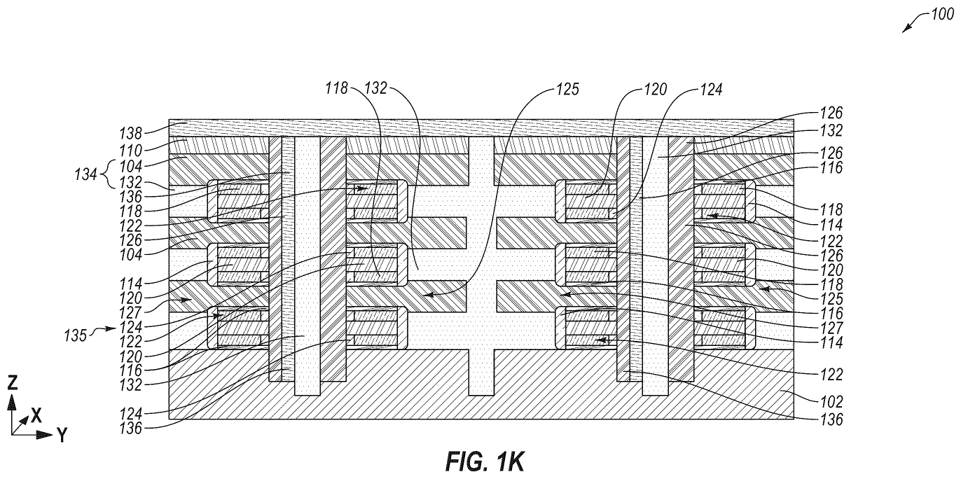

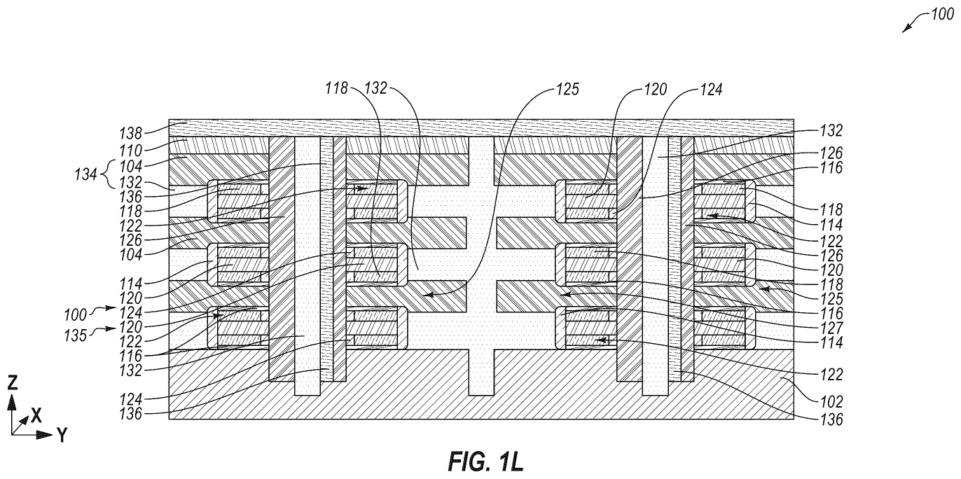

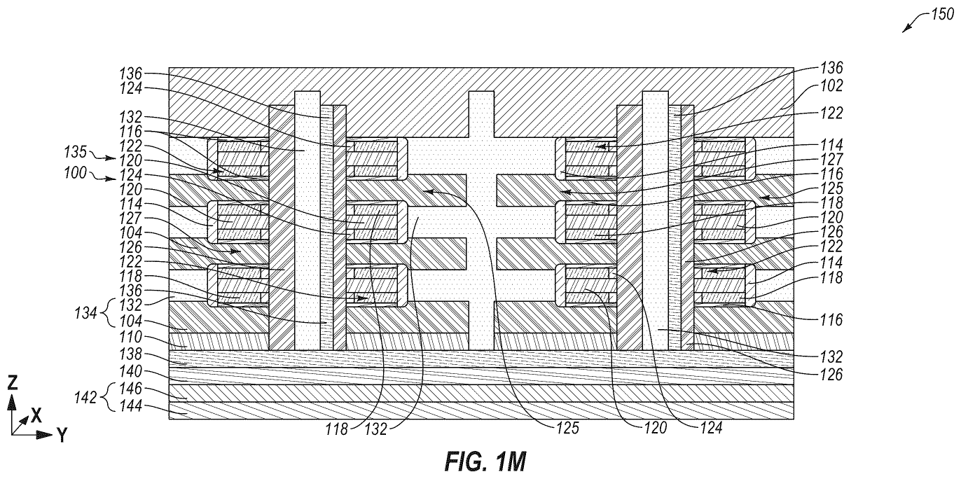

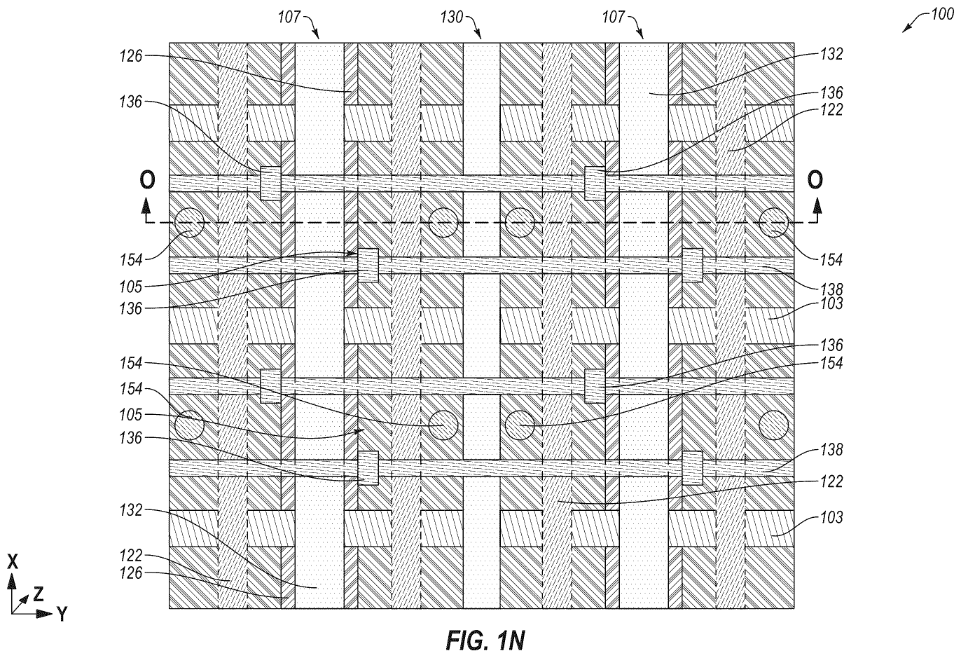

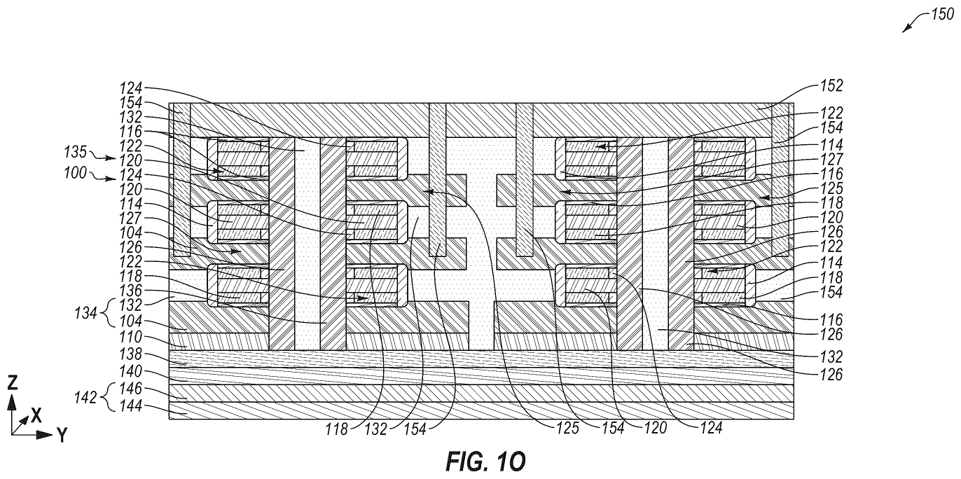

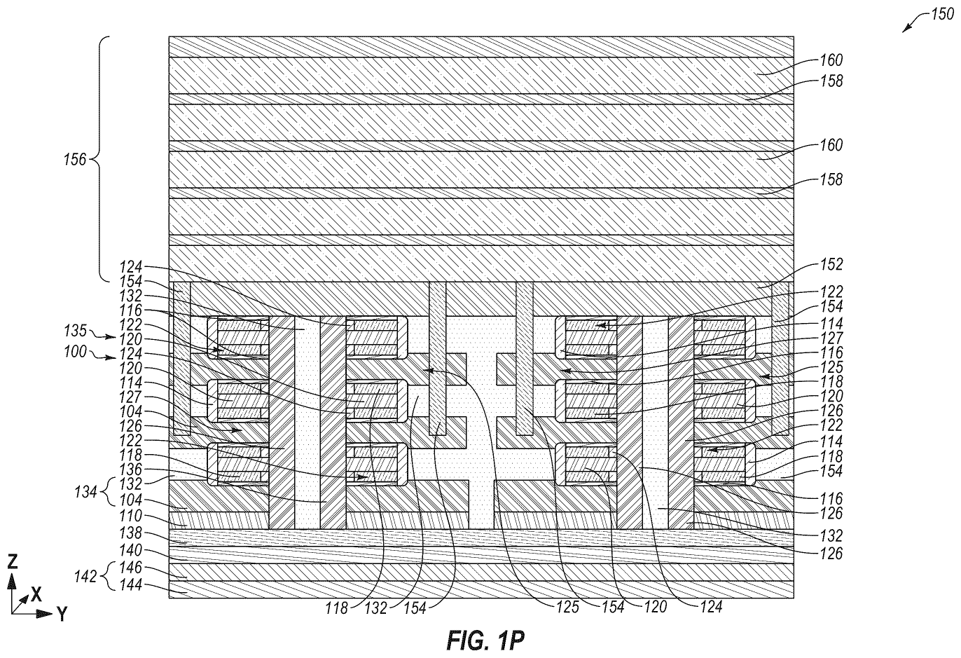

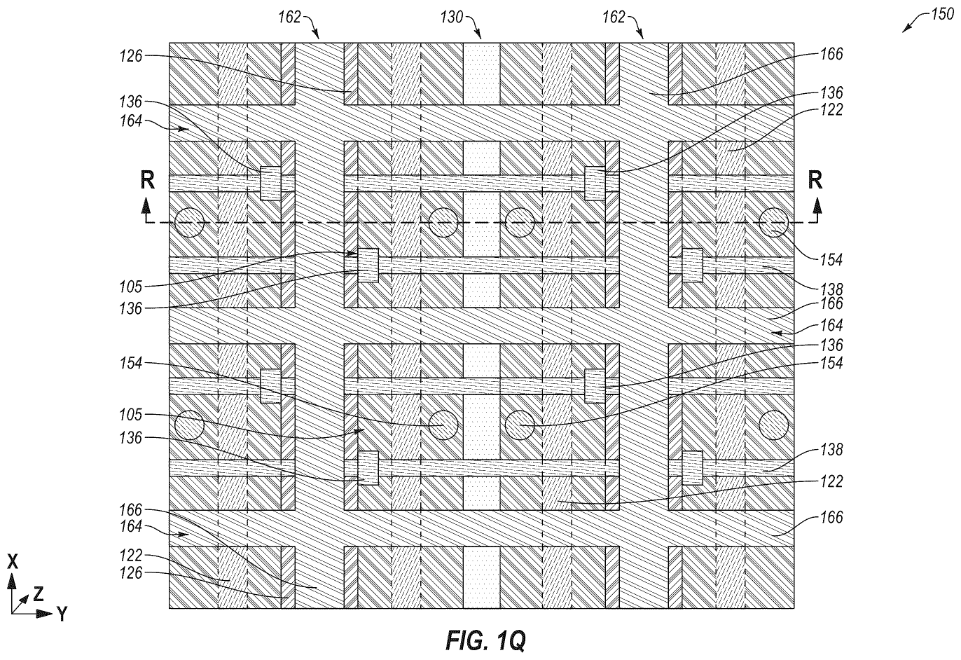

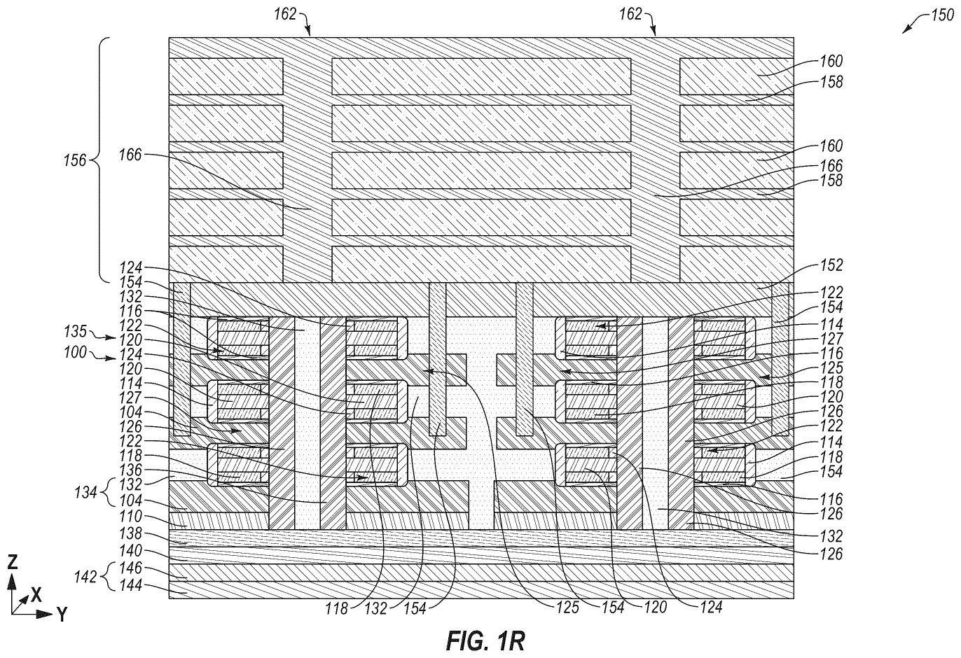

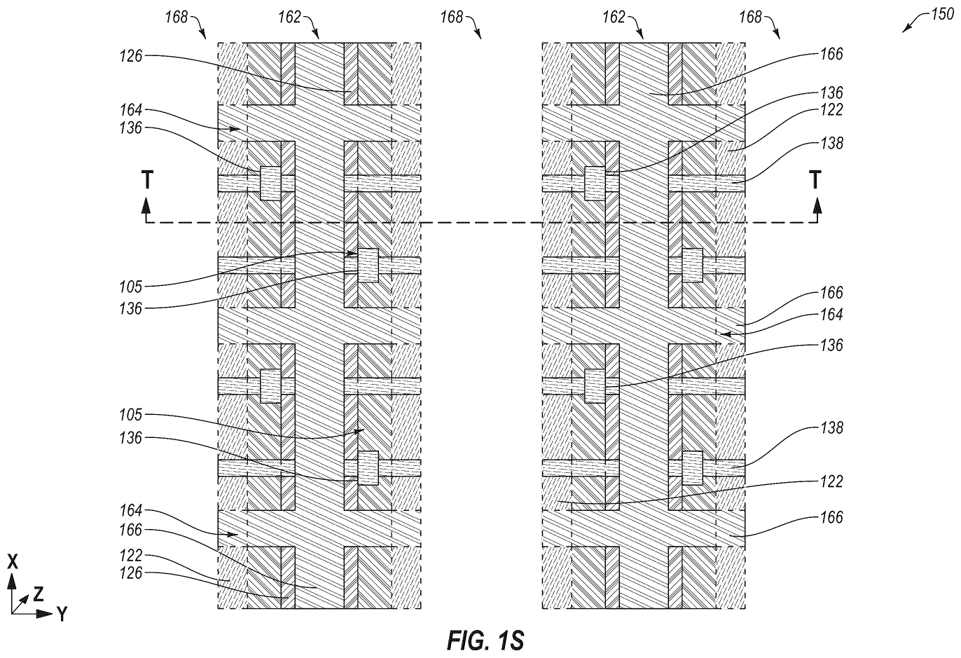

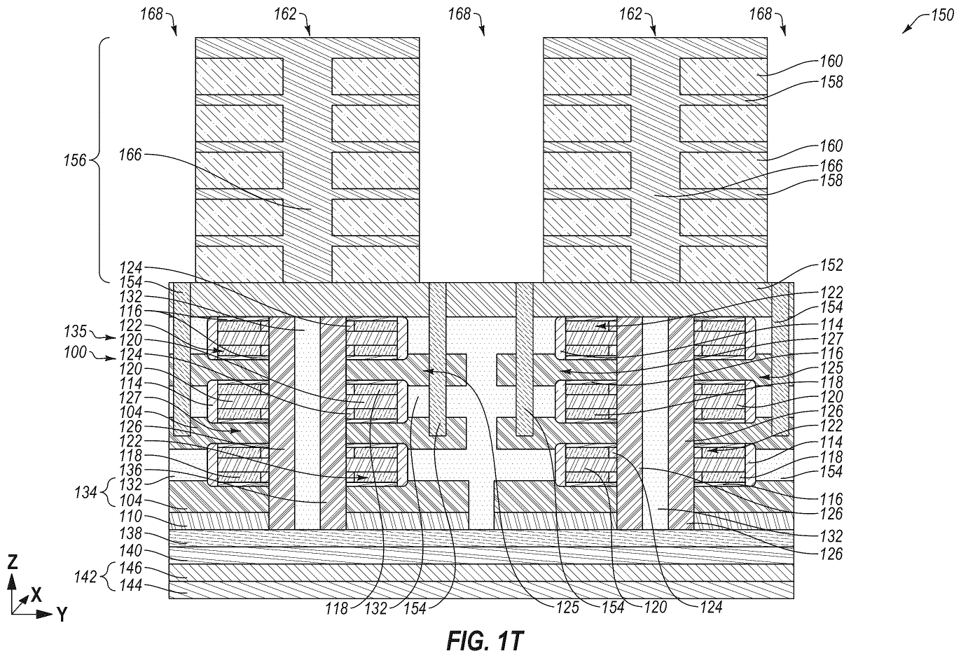

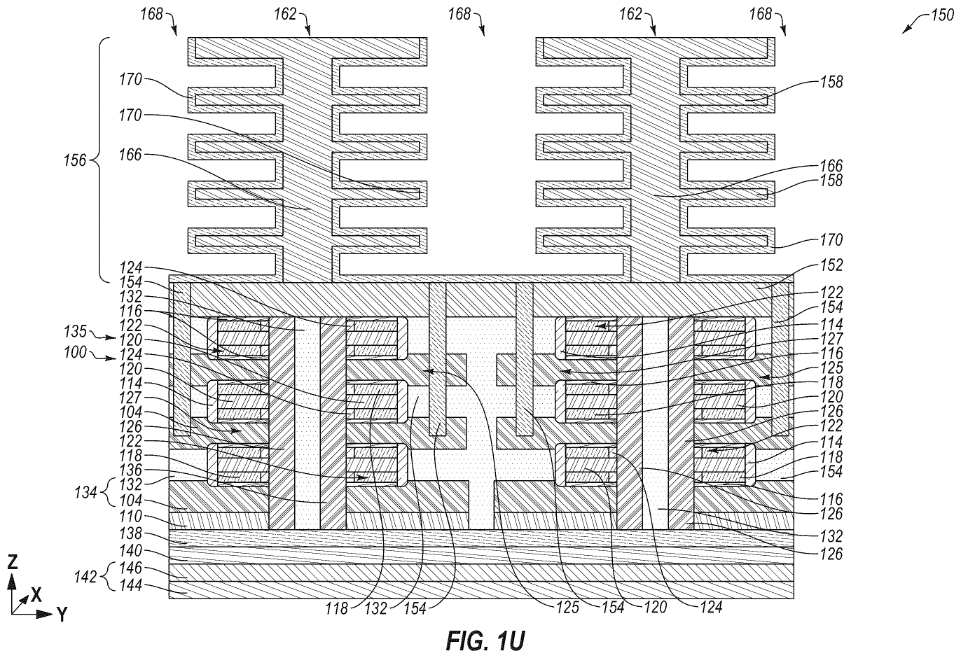

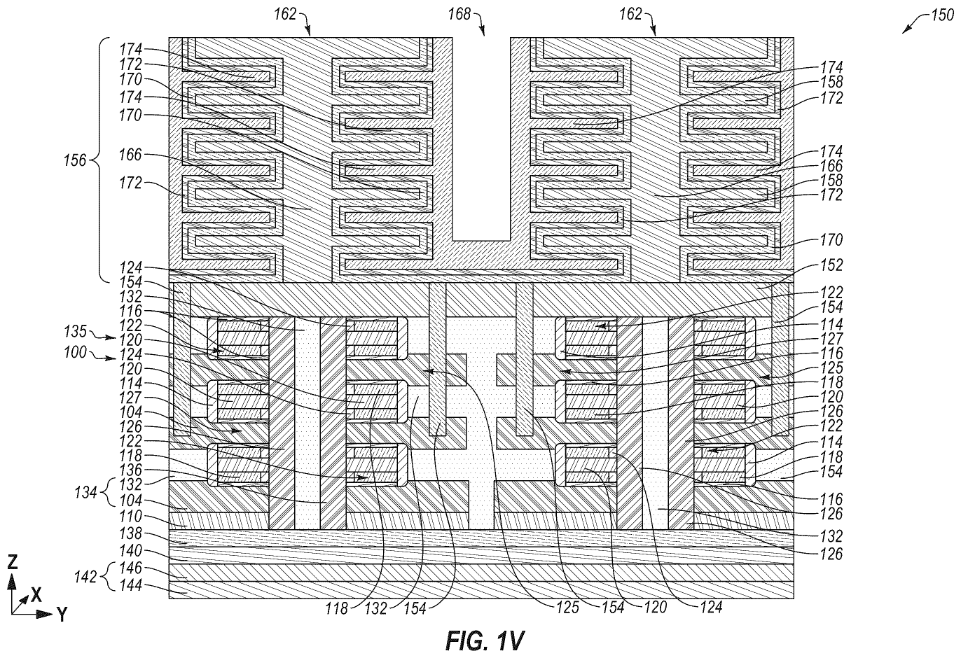

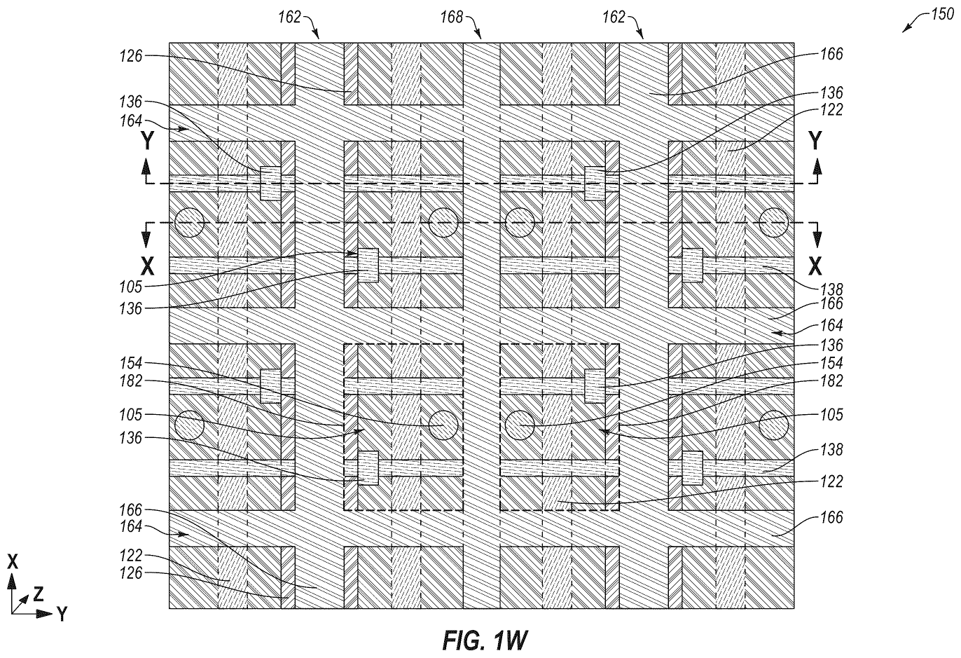

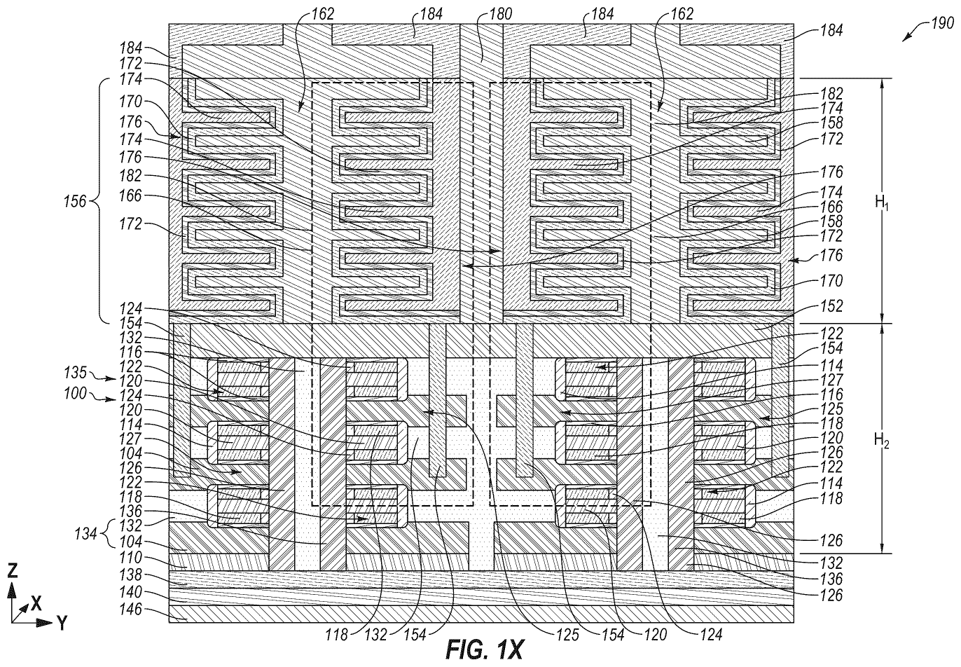

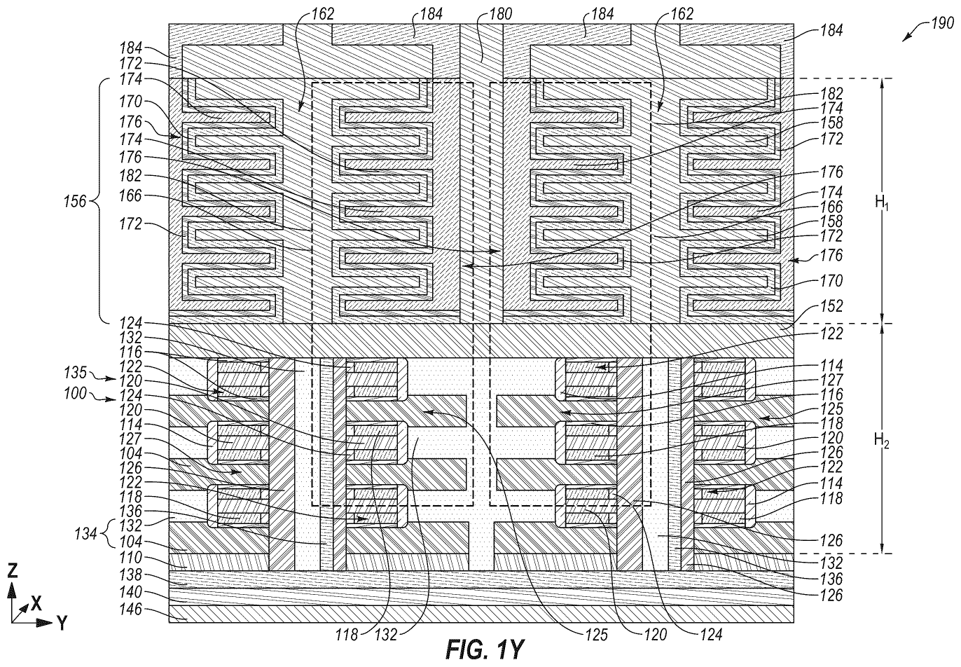

FIG. 1A through FIG. 1X are various views (described in further detail below) illustrating a microelectronic device structure at different processing stages of a method of forming a microelectronic device (e.g., a memory device, such as a DRAM memory device), in accordance with embodiments of the disclosure. With the description provided below, it will be readily apparent to one of ordinary skill in the art that the methods described herein may be used for forming various devices. In other words, the methods of the disclosure may be used whenever it is desired to form a microelectronic device.

FIG. 1A is a simplified, partial top-down view of a microelectronic device structure 100, in accordance with embodiments of the disclosure. FIG. 1B is a simplified, partial cross-sectional view of the microelectronic device structure 100 taken through section line B-B of FIG. 1A. With reference to FIG. 1A and FIG. 1B, the microelectronic device structure 100 includes active regions 105 (FIG. 1A) separated from one another by first trenches 107 extending in a first horizontal direction (e.g., in the X-direction) and a first insulative material 103 extending in a second horizontal direction (e.g., in the Y-direction). The first trenches 107 may be separated by the portions of the h first insulative material 103. In the view of FIG. 1A, it will be understood that the Z-axis is in and out of the view of the page.

Referring to FIG. 1B, the microelectronic device structure 100 includes a stack structure 101 comprising a vertically alternating (e.g., in the Z-direction) sequence of a first material 104 and a second material 106 arranged in tiers 108 and vertically overlying (e.g., in the Z-direction) a base structure 102.

The stack structure 101 may be formed to include any desired number of the tiers 108. By way of non-limiting example, the stack structure 101 may be formed to include two (2) of the tiers 108. In other embodiments, the stack structure 101 may be formed to include greater than or equal to four (4) of the tiers 108, such as greater than or equal to eight (8) of the tiers 108. As described in further detail herein, a quantity of the tiers 108 may correspond to a quantity of transistors (e.g., transistor structures 125 (FIG. 1X, FIG. 1Y)) of memory cells (e.g., memory cells 182 (FIG. 1X, FIG. 1Y)).

The base structure 102 may include a conventional silicon substrate (e.g., a conventional silicon wafer), or another bulk substrate comprising a semiconductive material. As used herein, the term “bulk substrate” means and includes not only silicon substrates, but also silicon-on-insulator (SOI) substrates, such as silicon-on-sapphire (SOS) substrates and silicon-on-glass (SOG) substrates, epitaxial layers of silicon on a base semiconductive foundation, and other substrates formed of and including one or more semiconductive materials (e.g., one or more of a silicon material, such monocrystalline silicon or polycrystalline silicon; silicon-germanium; germanium; gallium arsenide; a gallium nitride; and indium phosphide). In some embodiments, the base structure 102 comprises a silicon wafer.

The second material 106 of each of the tiers 108 of the stack structure 101 may be formed of and include at least one material that may be selectively removed relative to the first material 104. The second material 106 may be selectively etchable relative to the first material 104 during common (e.g., collective, mutual) exposure to a first etchant; and the first material 104 may be selectively etchable to the second material 106 during common exposure to a second, different etchant. As used herein, a material is “selectively etchable” relative to another material if the material exhibits an etch rate that is at least about five times (5×) greater than the etch rate of another material, such as about ten times (10×) greater, about twenty times (20×) greater, or about forty times (40×) greater.

The first material 104 may be formed of and include, for example, a semiconductive material (e.g., silicon) or an oxide material (e.g., silicon dioxide). In some embodiments, the first material 104 comprises silicon, such as epitaxially grown silicon. In some embodiments, the first material 104 comprises monocrystalline silicon.

The second material 106 may have a different material composition than the first material 104 and may have etch selectivity with respect to the first material 104. The second material 106 may be formed of and include one or more of silicon germanium, polysilicon, a nitride material (e.g., silicon nitride (Si₃N₄)), or an oxynitride material (e.g., silicon oxynitride). In some embodiments, such as where the first material 104 comprises silicon, the second material 106 comprises silicon germanium, such as epitaxially grown silicon germanium. In other embodiments, such as where the first material 104 comprises silicon, the second material 106 comprises polysilicon. In yet other embodiments, such as where the first material 104 comprises silicon dioxide, the second material 106 comprises silicon nitride or silicon oxynitride.

The first insulative material 103 may be formed of and include one or more of at least one insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In some embodiments, the first insulative material 103 is formed of and includes a dielectric oxide material, such as SiOₓ (e.g., SiO₂).

A second insulative material 110 may vertically overlie (e.g., in the Z-direction) the stack structure 101. The second insulative material 110 may be formed of and include insulative material, such as one or more of the materials described above with reference to the first insulative material 103. In some embodiments, the second insulative material 110 comprises silicon dioxide.

With reference to FIG. 1B, the first trenches 107 may vertically extend (e.g., in the Z-direction) through the second insulative material 110, the stack structure 101, and at least partially through the base structure 102. A horizontally extending (e.g., in the X-direction, in the Y-direction) surface of the base structure 102 may be exposed through the first trenches 107. In addition, horizontal sides of the first material 104 and the second material 106 may be exposed through the first trenches 107.

FIG. 1C is a simplified partial, cross-sectional view of the microelectronic device structure 100 at a processing stage subsequent to that illustrated in FIG. 1A and FIG. 1B. With reference to FIG. 1C, portions of the second material 106 exposed through the sidewalls defining the first trenches 107 may be selectively removed relative to the first material 104. Selective removal of the second material 106 relative to the first material 104 may form recesses 112 defined by exposed portions of the second material 106 recessed (e.g., in the Y-direction) relative to the first trenches 107 and exposed portions of the first material 104 (e.g., extending in the Y-direction).

In some embodiments, portions of the levels of the first material 104 are removed during removal of the second material 106 through the first trenches 107. In some embodiments, horizontally extending (e.g., in the Y-direction) portions of the levels of the first material 104 that are vertically separated (e.g., in the Z-direction) from one another by the recesses 112 may be partially removed such that portions of the first material 104 proximate the first trenches 107 and exposed by the recesses 112 have a smaller thickness (e.g., in the Z-direction) than other portions of the first material 104 distal from the first trenches 107.

In some embodiments, the portions of the second material 106 are selectively removed relative to the first material 104 by exposing the second material 106 to one or both of a dry etch process and a wet etch process. By way of non-limiting example, the second material 106 may be removed selective to the first material 104 by exposing the second material 106 to a dry etch including one or both of hydrogen fluoride (HF) and methanol (CH₃OH); followed by a plasma treatment with one or more of carbon tetrafluoride (CF₄), fluorine (F₂), ammonia (NH₃), argon, and chlorine trifluoride (ClF₃).

FIG. 1D is a simplified partial, cross-sectional view of the microelectronic device structure 100 at a processing stage subsequent to that illustrated in FIG. 1C. After forming the recesses 112, a third insulative material 114 may be formed within the first trenches 107 and within the recesses 112 on exposed surfaces of the first material 104, the second material 106, and the base structure 102.

The third insulative material 114 may be formed by, for example, depositing a liner material comprising the third insulative material 114 and removing portions of the liner material from surfaces of the base structure 102 and from horizontally extending (e.g., in the X-direction, in the Y-direction) surfaces of the first material 104 proximate the first trenches 107. The third insulative material 114 may remain on surfaces of the second material 106 and vertically extend (e.g., in the Z-direction) between vertically neighboring (e.g., in the Z-direction) levels of the first material 104 at locations distal from the first trenches 107.

The third insulative material 114 may be formed of and include insulative material having an etch selectivity with respect to the first material 104, the second material 106, and a dielectric material 116. In some embodiments, the third insulative material 114 comprises a nitride material (e.g., silicon nitride (Si₃N₄)) or an oxynitride material (e.g., silicon oxynitride). In some embodiments, the third insulative material 114 comprises silicon nitride.

After forming third insulative material 114, a dielectric material 116 may be formed on horizontally extending (e.g., in the X-direction, in the Y-direction) surfaces of the first material 104. In some embodiments, the dielectric material 116 is grown on exposed surfaces of the first material 104. By way of non-limiting example, the dielectric material 116 may be formed by exposing surfaces of the first material 104 to oxygen at an elevated temperature (e.g., at a temperature within a range of from about 900° C. to about 1,200° C.).

In other embodiments, the dielectric material 116 is formed by depositing the dielectric material 116 on surfaces defining the recesses 112 (e.g., horizontally extending (e.g., in the X-direction, in the Y-direction) surfaces of the first material 104) and vertically extending (e.g., in the Z-direction) surfaces of the third insulative material 114. The portions of the dielectric material 116 on vertically extending surfaces of the third insulative material 114 and on surfaces within the first trenches 107 and outside of the first trenches 107 may be removed.

The dielectric material 116 may also be referred to herein as a “gate dielectric material.” As described in further detail herein, the dielectric material 116 is vertically interposed between (e.g., in the Z-direction) the first material 104 and a conductive material (e.g., conductive material 118 (FIG. 1E)).

The dielectric material 116 may be formed of and include insulative material. By way of non-limiting example, the dielectric material 116 may comprise one or more of phosphosilicate glass, borosilicate glass, borophosphosilicate glass (BPSG), fluorosilicate glass, silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide, a nitride material, (e.g., silicon nitride (Si₃N₄)), an oxynitride (e.g., silicon oxynitride), another gate dielectric material, a dielectric carbon nitride material (e.g., silicon carbon nitride (SiCN)), or a dielectric carboxynitride material (e.g., silicon carboxynitride (SiOCN)).

FIG. 1E is a simplified partial, cross-sectional view of the microelectronic device structure 100 at a processing stage subsequent to that illustrated in FIG. 1D. With reference to FIG. 1E, after forming the dielectric material 116, a conductive material 118 may be formed within the first trenches 107 and the recesses 112 (FIG. 1D) on surfaces of the dielectric material 116 within the recesses 112 and on vertically extending (e.g., in the Z-direction) surfaces of the first material 104 defining sidewalls of the first trenches 107.

After forming the conductive material 118, a fourth insulative material 120 may be formed on surfaces of the conductive material 118 within the recesses 112 (FIG. 1D) and within the first trenches 107. In some embodiments, the fourth insulative material 120 substantially fills remaining portions of the recesses 112.

The conductive material 118 may be formed of and include conductive material, such as, for example, one or more of a metal (e.g., tungsten, titanium, nickel, platinum, rhodium, ruthenium, aluminum, copper, molybdenum, iridium, silver, gold), a metal alloy, a metal-containing material (e.g., metal nitrides, metal silicides, metal carbides, metal oxides), a material including at least one of titanium nitride (TiN), tantalum nitride (TaN), tungsten nitride (WN), titanium aluminum nitride (TiAlN), iridium oxide (IrOₓ), ruthenium oxide (RuOₓ), alloys thereof, a conductively doped semiconductor material (e.g., conductively doped silicon, conductively doped germanium, conductively doped silicon germanium, etc.), polysilicon, or other materials exhibiting electrical conductivity.

The fourth insulative material 120 may be formed of and include insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In some embodiments, the fourth insulative material 120 is formed of and includes a dielectric oxide material, such as SiOₓ (e.g., SiO₂).

FIG. 1F is a simplified partial, cross-sectional view of the microelectronic device structure 100 at a processing stage subsequent to that illustrated in FIG. 1E. After forming the conductive material 118 and the fourth insulative material 120, portions of the fourth insulative material 120 may be removed from within the first trenches 107 and from vertically uppermost (e.g., in the Z-direction) surfaces of the microelectronic device structure 100. The fourth insulative material 120 may remain at portions corresponding to the locations of the recesses 112 (FIG. 1D) vertically between (e.g., in the Z-direction) levels of the first material 104.

After removing the portions of the fourth insulative material 120, portions of the conductive material 118 may be removed from within the first trenches 107 and from vertically uppermost (e.g., in the Z-direction) surfaces of the microelectronic device structure 100. Exposed portions of the conductive material 118 defining the sidewalls of the first trenches 107 may be recessed (e.g., in the Y-direction) relative to the surfaces of the fourth insulative material 120. In some embodiments, the conductive material 118 is selectively removed (e.g., in the Y-direction) relative to the fourth insulative material 120 and the first material 104 by exposing the conductive material 118 to a dry etchant comprising, for example, sulfur hexafluoride (SF₆) and nitrogen (N₂), nitrogen trifluoride (NF₃), hydrogen fluoride (HF), fluorine (F₂), and methyl fluoride (CH₃F). However, the disclosure is not so limited and the conductive material 118 may be selectively removed relative to the fourth insulative material 120 and the first material 104.

After removing the portions of the conductive material 118, remaining portions of the conductive material 118 may form conductive structures 122. The conductive structures 122 may vertically overlie (e.g., in the Z-direction) and vertically underlie (e.g., in the Z-direction) portions of each of the first materials 104. In some embodiments, vertically neighboring (e.g., in the Z-direction) conductive structures 122 between vertically neighboring (e.g., in the Z-direction) levels of the first material 104 are spaced from each other by the fourth insulative material 120. The dielectric material 116 may vertically intervene (e.g., in the Z-direction) between the conductive structures 122 and the first material 104.

The conductive structures 122 may horizontally extend (e.g., in the X-direction) as lines and may extend through an array region of the microelectronic device structure 100. As described in further detail herein, the conductive structures 122 may individually be referred to herein as “first conductive lines,” “access lines,” or “word lines.”

After recessing portions of the conductive material 118 and forming the conductive structures 122, a fifth insulative material 124 may be formed between horizontal edges (e.g., in the Y-direction) of the conductive structures 122 and the first trenches 107. After forming the fifth insulative material 124, portions of the fifth insulative material 124 within the first trenches 107 may be removed.

The fifth insulative material 124 may be formed of and include one or more of the materials described above with reference to the third insulative material 114. In some embodiments, the fifth insulative material 124 comprises substantially the same material composition as the third insulative material 114. In some embodiments, the fifth insulative material 124 comprises silicon nitride.

Transistor structures 125 may be formed within the levels of the first material 104 between vertically neighboring (e.g., in the Z-direction) levels of the second material 106. The transistor structures 125 may individually comprise a channel region 127 vertically between (e.g., in the Z-direction) vertically neighboring (e.g., in the Z-direction) conductive structures 122. The conductive structures 122 are separated from the channel regions 127 by the dielectric material 116. In FIG. 1F, one of the transistor structures 125 is illustrated in dashed box 129. With continued reference to FIG. 1F, in some embodiments, the microelectronic device structure 100 includes two levels of transistor structures 125 vertically spaced (e.g., in the Z-direction) from one another by, for example, the fourth insulative material 120. In some embodiments, the stack structure 101 comprises two vertically stacked transistor structures 125.

In some embodiments, the transistor structures 125 individually comprise so-called “gate-all-around” (GAA) transistors. By way of non-limiting example, the conductive structures 122 may substantially surround the channel regions 127 of the transistor structures 125 and each channel region 127 may be surrounded by portions of the conductive structures 122 vertically above (e.g., in the Z-direction), vertically below (e.g., in the Z-direction), and horizontally around (e.g., in the X-direction, such as between the first insulative material 103 (FIG. 1A) and the channel region 127) the channel region 127.

In some embodiments, horizontal boundaries (e.g., in the X-direction, in the Y-direction) of each of the vertically neighboring (e.g., in the Z-direction) transistor structures 125 are individually located within horizontal boundaries of the other transistor structures 125 directly vertically neighboring (e.g., in the Z-direction) the transistor structures 125. In some embodiments, the horizontal boundaries of each of the transistor structures 125 directly vertically neighboring one another are shared (e.g., the same).

In some embodiments, the conductive structures 122 are vertically stacked (e.g., in the Z-direction) with respect to one another and vertically spaced (e.g., in the Z-direction) from one another by the channel regions 127, the dielectric materials 116, and the fourth insulative material 120.

In some embodiments, the transistor structures 125 individually comprise a so-called planar transistor, wherein the source region and the drain region are located within the same plane as the channel region 127. Individual transistor structures 125 may be vertically stacked (e.g., in the Z-direction) over one another and individually comprise a planar transistor.

With continued reference to FIG. 1F, a vertical thickness (e.g., in the Z-direction) T₁ of the dielectric material 116 may be within a range of from about 5 nanometers (nm) to about 10 nm, such as from about 5 nm to about 7.5 nm, or from about 7.5 nm to about 10 nm. In some embodiments, the vertical thickness T₁ is about 7 nm. However, the disclosure is not so limited and the vertical thickness T₁ may be different than those described.

A vertical thickness (e.g., in the Z-direction) T₂ of the conductive structures 122 may be within a range of from about 15 nm to about 30 nm, such as from about 15 nm to about 20 nm, from about 20 nm to about 25 nm, or from about 25 nm to about 30 nm. In some embodiments, the vertical thickness T₂ is about 20 nm. However, the disclosure is not so limited, and the vertical thickness T₂ may be different than those described.

A vertical thickness (e.g., in the Z-direction) T₃ of the channel regions 127 of the transistor structures 125 may be within a range of from about 5 nm to about 20 nm, such as from about 5 nm to about 10 nm, from about 10 nm to about 15 nm, or from about 15 nm to about 20 nm. In some embodiments, the vertical thickness T₃ is about 8 nm. However, the disclosure is not so limited and the vertical thickness T₃ may be different than those described. It will be understood that, for clarity and case of understanding the description, FIG. 1F and the other drawings herein are not to scale.

FIG. 1G is a simplified partial, top-down view of the microelectronic device structure 100 at a processing stage subsequent to that illustrated in FIG. 1F. FIG. 1H is a simplified partial, cross-sectional view of the microelectronic device structure 100 at a processing stage subsequent to that illustrated in FIG. 1G. After forming the fifth insulative material 124, a conductive material 126 may be formed within the first trenches 107 and between horizontally neighboring (e.g., in the X-direction) portions of the first insulative material 103. Accordingly, different portions of the conductive material 126 may be electrically isolated from one another by the first insulative material 103. After forming the conductive material 126, horizontally extending portions (e.g., in the X-direction, in the Y-direction) of the conductive material 126 may be removed, such as by exposing the conductive material 126 to a dry etch process including one or more of trichlorofluoromethane (CFCL₃), chlorotrifluoromethane (CF₃CL), bromotrifluoromethane (CF₃Br), CF₄, hexafluorocthane (C₂F₆), SF₆, and a mixture of hydrogen bromide (HBr) and oxygen (O₂). Removing the horizontally extending portions of the conductive material 126 may electrically isolate different portions of the conductive material 126 separated from one another by the first trenches 107.

The conductive material 126 may contact the sidewalls of the levels of the first material 104 and the sides of the fifth insulative material 124 and the fourth insulative material 120. In use and operation, the conductive material 126 may be in electrical communication with the first material 104. In some such embodiments, electrical current flows between the conductive material 126 and the first material 104 (e.g., from the conductive material 126 to the first material 104, from the first material 104 to the conductive material 126).

In some embodiments, after removing a vertically lowermost (e.g., in the Z-direction) portion of the conductive material 126, portions of the base structure 102 are removed through the first trenches 107.

The conductive material 126 may be formed of and include conductive material, such as one or more of the materials described above with reference to the conductive material 118. In some embodiments, the conductive material comprises conductively doped polysilicon, such as N+ doped polysilicon.

FIG. 1I is a simplified partial, cross-sectional view of the microelectronic device structure 100 at a processing stage subsequent to that illustrated in FIG. 1G and FIG. 1H. After forming the conductive material 126, a mask material 128 may be formed over the microelectronic device structure 100. In some embodiments, the mask material 128 vertically overlies (e.g., in the Z-direction) and covers the first trenches 107.

Second trenches 130 may be formed within the stack structure 101 through the mask material 128 between horizontally neighboring (e.g., in the Y-direction) first trenches 107. In some embodiments, the second trenches 130 may horizontally extend in a horizontal direction (e.g., in the X-direction) substantially parallel to the first trenches 107 and substantially parallel to the conductive structures 122. The second trenches 130 may vertically extend (e.g., in the Z-direction) at least through a portion of the base structure 102.

The mask material 128 may be formed of and include one or one or more of silicon nitride, silicon oxycarbide, a silicon carboxynitride material, amorphous carbon, polysilicon, a dielectric anti-reflective coating (DARC) material, a bottom anti-reflective coating (BARC) material, a metal nitride (e.g., titanium nitride, tungsten nitride, tantalum nitride, aluminum nitride), a metal oxide (e.g., aluminum oxide, titanium oxide, tungsten oxide, tantalum oxide, hafnium oxide, zirconium oxide), or an oxynitride material. In some embodiments, the mask material 128 comprises silicon nitride.

After forming the second trenches 130, the second material 106 (FIG. 1H) may be selectively removed relative to the first material 104 through the second trenches 130, leaving voids vertically between (e.g., in the Z-direction) vertically neighboring (e.g., in the Z-direction) levels of the first material 104. Removal of the second material 106 through the second trenches 130 may expose vertically extending (e.g., in the Z-direction) sidewalls of the third insulative material 114. In some embodiments, the third insulative material 114 serves as an etch stop material and substantially reduce or prevent removal of the conductive material 118 of the conductive structures 122 during selective removal of the second materials 106.

The second material 106 may be selectively removed relative to the first material 104 by exposing the second material 106 to one or both of a vapor etching process and a dry etch process. By way of non-limiting example, the second material 106 may be removed selective to the first material 104 by exposing the second material 106 to a vapor etch comprising hydrogen fluoride and methanol (CH₃OH), followed by exposing the second material 106 to a plasma comprising one or more of CF₄, F₂, NH₃, argon (Ar), and chlorine trifluoride (ClF₃) (e.g., CF₄, a mixture of F₂ and NH₃, or a mixture of Ar and Fc).

FIG. 1J is a simplified, partial top-down view of the microelectronic device structure 100 at a processing stage subsequent to that illustrated in FIG. 1I. FIG. 1K is a simplified, partial cross-sectional view of the microelectronic device structure 100 taken through section line K-K of FIG. 1J. FIG. 1L is a simplified, partial cross-sectional view of the microelectronic device structure 100 taken through section line L-L of FIG. 1J. In FIG. 1J, the conductive structures 122 are illustrated in broken lines to indicate that they are located in a different vertical plane (e.g., in the Z-direction) than other portions of the microelectronic device structure 100, such as vertically below (e.g., in the Z-direction) a vertically uppermost (e.g., in the Z-direction) upper surface of the microelectronic device structure 100.

With collective reference to FIG. 1J through FIG. 1L, after removing the levels of the second material 106 (FIG. 1H) through the second trenches 130 (FIG. 1I), portions of conductive material 126 horizontally extending (e.g., in the Y-direction) may be removed to electrically isolate horizontally neighboring (e.g., in the Y-direction) portions of the conductive material 126. In some embodiments, after removing the portions of the conductive material 126, each of the first trenches 107, the second trenches 130, and the regions vertically between (e.g., in the Z-direction) vertically neighboring (e.g., in the Z-direction) levels of the first material 104 may be filled with a sixth insulative material 132. The vertical levels of the sixth insulative material 132 may vertically alternate with the vertical levels of the first material 104 and may form a stack structure 135 comprising a vertically alternative sequence of tiers 134, each tier 134 comprising a vertical level of the first material 104 and a vertical level of the sixth insulative material 132.

After forming the sixth insulative material 132, portions of the sixth insulative material 132 vertically overlying (e.g., in the Z-direction) the microelectronic device structure 100 may be removed, such as by chemical mechanical planarization (CMP) or by etching. After removing the portions of the sixth insulative material 132, the mask material 128 (FIG. 1H) may be removed to expose the second insulative material 110.

With continued reference to FIG. 1J through FIG. 1L, after forming the sixth insulative material 132, first conductive contact structures 136 may be formed to vertically extend (e.g., in the Z-direction) adjacent to and in contact with the conductive material 126. In some embodiments, portions of the sixth insulative material 132 and the conductive material 126 are removed and replaced with a conductive material to form the first conductive contact structures 136.

First conductive contact structures 136 horizontally neighboring one another in a first direction (e.g., in the X-direction) may be horizontally offset from one another in a second direction (e.g., in the Y-direction); and first conductive contact structures 136 horizontally neighboring one another in the second direction may be horizontally offset from one another in the first direction. In some such embodiments, nearest first conductive contact structures 136 (e.g., first conductive contact structures most proximate one another) are horizontally offset from each other in the first direction and the second direction and the first conductive contact structures 136 are staggered. By way of non-limiting example, a first conductive contact structure 136 on a first side of the sixth insulative material 132 within one of the first trenches 107 may be horizontally spaced (e.g., in the X-direction) from a horizontally neighboring (e.g., in the Y-direction) first conductive contact structure 136 on a second side of the sixth insulative material 132 within the first trench 107.

In some embodiments, first conductive contact structures 136 nearest one another are horizontally offset from one another in each of a first horizontal direction (e.g., in the X-direction) and in a second horizontal direction (e.g., in the Y-direction). The second horizontal direction may be substantially perpendicular to the first horizontal direction.

After forming the first conductive contact structures 136, conductive lines 138 may be formed vertically over (e.g., in the Z-direction) the microelectronic device structure 100 and in contact with the first conductive contact structures 136. The conductive lines 138 may horizontally extend (e.g., in the Y-direction) substantially perpendicularly to the conductive structures 122. The conductive lines 138 may be employed as digit lines (e.g., data lines, bit lines). Since the first conductive contact structures 136 are in contact with the conductive lines 138 and configured to be electrically connected to the conductive lines 138, the first conductive contact structures 136 may be employed as digit line contacts (also referred to herein as “digit line contact structures”). The conductive lines 138 may vertically overlie (e.g., in the Z-direction) the conductive structures 122. With reference to FIG. 1J, while the conductive structures 122 are illustrated in the top-down view of FIG. 1J, it will be understood that the conductive structures 122 are vertically below (e.g., in the Z-direction) the conductive lines 138 do not contact the conductive lines 138. The conductive structures 122 are illustrated in broken lines in FIG. 1J and the other top-down views herein to indicate that they are located below other portions of the microelectronic device structure 100 (e.g., such as the conductive lines 138). The relative vertical locations (e.g., in the Z-direction) of different components of the microelectronic device structure 100 are best illustrated in the cross-sectional views (e.g., such as FIG. 1K and FIG. 1L), while the relative horizontal positioning (e.g., in the X-direction, in the Y-direction) are best illustrated in the top-down views (e.g., such as FIG. 1J).

The conductive lines 138 may individually be in contact with first conductive contact structures 136 that are horizontally aligned with one another in a first direction (e.g., in the X-direction) and horizontally spaced from one another in a second direction (e.g., in the Y-direction). In some such embodiments, an individual conductive line 138 may be in contact with first conductive contact structures 136 that are located within horizontal boundaries (e.g., in the X-direction) of one another.

The first conductive contact structures 136 may electrically connect the conductive line 138 in contact with the first conductive contact structures 136 to the first materials 104 of the levels of the first materials 104 by means of the conductive material 126. In use and operation, application of a voltage to, for example, the conductive structures 122 may induce an electric current in the first material 104 vertically between (e.g., in the Z-direction) the conductive structures 122 and electrically connect the conductive line 138 to a storage structure (e.g., storage device 176 (FIG. 1X, FIG. 1Y)) in electrical communication with the first material 104.

The conductive lines 138 may be formed by, for example, forming a conductive material vertically over (e.g., in the Z-direction) the microelectronic device structure 100, such as on the second insulative material 110 and in contact with the first conductive contact structures 136. After forming the conductive material, the conductive material may be patterned into the conductive lines 138, such as by exposing the conductive material to one or more dry etchants through, for example, a mask material.

After forming the conductive lines 138, an insulative material may be formed over the microelectronic device structure 100 and horizontally between (e.g., in the X-direction) the conductive lines 138. The insulative material may be formed of and include one or more of the materials described above with reference to the first insulative material 103. In some embodiments, the insulative material comprises an oxide material, such as silicon dioxide.

After forming the insulative material, the microelectronic device structure 100 may be exposed to a CMP process to remove portions of the insulative material vertically overlying (e.g., in the Z-direction) the conductive lines 138 and to expose surfaces of the conductive lines 138. After exposing the microelectronic device structure 100 to the CMP process, a vertically uppermost (e.g., in the Z-direction) surface of the microelectronic device structure 100 is defined at least by surfaces of the conductive lines 138 and surfaces of the insulative material. The insulative material is not illustrated in FIG. 1K and FIG. 1L since the cross-sectional views of FIG. 1K and FIG. 1L are along different conductive lines 138, however, it will be understood that the insulative material may vertically overlie and second insulative material 110 in regions horizontally between (e.g., in the X-direction) horizontally neighboring (e.g., in the X-direction) conductive lines 138.

The first conductive contact structures 136 and the conductive lines 138 may individually be formed of and include conductive material, such as one or more of the materials described above with reference to the conductive material 118. In some embodiments, the first conductive contact structures 136 and the conductive lines 138 individually comprise tungsten.

While the conductive material 126 has been described and illustrated as being formed as a liner material within the first trenches 107 (FIG. 1G), the disclosure is not so limited. In other embodiments, the conductive material 126 may be formed as contact structures, substantially similar to the conductive contact structures 136, the conductive material 126 in contact with the channel region 127 of the transistor structures 125 and horizontally intervening (e.g., in the Y-direction) between the channel region 127 of the transistor structures 125 and the conductive contact structures 136. In other embodiments, the conductive material 126 may selectively be epitaxially grown on the first material 104 relative to the first insulative material 103 (FIG. 1A, FIG. 1G) such that portions of the conductive material 126 on horizontally opposing sides (e.g., in the Y-direction) of the first trenches 107 are electrically isolated from one another. In some embodiments, the conductive material 126 is doped with one or more dopants to increase an electrical conductivity of the conductive material 126. By way of non-limiting example, portions of the conductive material 126 within horizontal boundaries (e.g., in the X-direction) of the conductive contact structures 136 and horizontally intervening (e.g., in the Y-direction) between the conductive contact structures 136 and the channel regions 127 of the transistor structures 125 may be doped while other positions of the conductive material 126 may not be doped.

FIG. 1M is a simplified, partial cross-sectional view of the microelectronic device structure 100 at a processing stage subsequent to that illustrated in FIG. 1J through FIG. 1L. The cross-sectional view of FIG. 1M is taken through the same plane as that illustrated in FIG. 1K, but at a subsequent processing stage than that illustrated and described with reference to FIG. 1K.

With reference to FIG. 1K, after forming the first conductive contact structures 136, the conductive lines 138, and the insulative material, a seventh insulative material 140 is formed over the conductive lines 138 and the insulative material. The seventh insulative material 140 may be formed of and include one or more of the materials described above with reference to the first insulative material 103. In some embodiments, the seventh insulative material 140 comprises an oxide material, such as silicon dioxide.

After forming the seventh insulative material 140, the microelectronic device structure 100 may be vertically inverted (e.g., flipped upside down in the Z-direction) and attached (e.g., bonded) to a carrier wafer 142 comprising a second base structure 144 and an oxide material 146 overlying the second base structure 144 to form a microelectronic device structure assembly 150 comprising the microelectronic device structure 100 and the carrier wafer 142. The carrier wafer 142 may be configured to facilitate safe handling of the microelectronic device structure assembly 150 for further processing of the microelectronic device structure 100. The carrier wafer 142 may comprise a conventional carrier structure and is therefore not described in detail herein.

The oxide material 146 may be formed of and include an oxide insulative material, such as at least one dielectric oxide material (e.g., one or more of a silicon oxide (SiOₓ), phosphosilicate glass, borosilicate glass, borophosphosilicate glass, fluorosilicate glass, AlOₓ, HfOₓ, NbOₓ, TiOₓ, ZrOₓ, TaOₓ, and MgOₓ). In some embodiments, the oxide material 146 comprises silicon dioxide. In some embodiments, the oxide material 146 and the seventh insulative material 140 comprises substantially the same material composition (e.g., silicon dioxide).

The carrier wafer 142 may be attached to the microelectronic device structure 100 by contacting the seventh insulative material 140 of the microelectronic device structure 100 with the oxide material 146 of the carrier wafer 142. After the seventh insulative material 140 and the oxide material 146 are in contact, the microelectronic device structure 100 and the carrier wafer 142 may be exposed to annealing conditions to form bonds (e.g., oxide-to-oxide bonds) between the seventh insulative material 140 of the microelectronic device structure 100 and the oxide material 146 of the carrier wafer 142 to form the microelectronic device structure assembly 150. In some embodiments, the microelectronic device structure 100 and the carrier wafer 142 are exposed to a temperature greater than, for example, 800° C., to form the oxide-to-oxide bonds and attach the microelectronic device structure 100 to the carrier wafer 142.

FIG. 1N is a simplified, partial top-down view of the microelectronic device structure assembly 150 at a processing stage subsequent to that illustrated in FIG. 1M. FIG. 1O is a simplified, partial cross-sectional view of the microelectronic device structure assembly 150 taken through section line O—O of FIG. 1N.

With reference to FIG. 1O, after attaching the microelectronic device structure 100 to the carrier wafer 142, the base structure 102 (FIG. 1M) may be removed (e.g., thinned, etched), such as by exposing the base structure 102 to one or more etchants or by exposing the base structure 102 to a CMP process. In some embodiments, the base structure 102 is removed by exposing the base structure 102 to an etchant formulated and configured to stop on an insulative material (e.g., the sixth insulative material 132, the third insulative material 114, the dielectric material 116, the fifth insulative material 124).

After removing the base structure 102 (FIG. 1M), an eighth insulative material 152 is formed over the microelectronic device structure 100 to cover exposed portions of the first conductive contact structures 136 (FIG. 1M) and the conductive material 126. The eighth insulative material 152 may be formed of and include insulative material, such as one or more of the materials described above with reference to the first insulative material 103. In some embodiments, the eighth insulative material 152 comprises silicon dioxide.

After forming the eighth insulative material 152, second conductive contact structures 154 may be formed through the eighth insulative material 152 and individually in contact with the transistor structures 125. In some embodiments, each second conductive contact structure 154 vertically extends (e.g., in the Z-direction) through portions of two vertically neighboring (e.g., in the Z-direction) transistor structures 125. In some embodiments, each of the second conductive contact structures 154 vertically extends (e.g., in the Z-direction) substantially completely through an uppermost transistor structure 125 (e.g., the first material 104 of the vertically uppermost transistor structure 125) and at least partially vertically through a vertically underlying (e.g., in the Z-direction) transistor structure 125.

In some embodiments, the second conductive contact structures 154 are in contact with, for example, drain regions of the transistor structures 125 and the first conductive contact structures 136 are in contact with source regions of the transistor structures 125, the channel region 127 horizontally between (e.g., in the Y-direction) the source regions and the drain regions. Portions of the second conductive contact structures 154 within the first materials 104 of the transistor structures 125 may be substantially surrounded (e.g., completely surrounded) by the first material 104 within the vertical boundaries (e.g., in the Z-direction) of the first material 104 through which the second conductive contact structures 154 vertically extend.

With reference to FIG. 1N, the second conductive contact structures 154 horizontally neighboring one another in a first direction (e.g., in the Y-direction) may individually be horizontally aligned with one another in a second direction (e.g., in the X-direction); and second conductive contact structures 154 horizontally neighboring one another in the second direction (e.g., in the X-direction) may be horizontally aligned with one another in the first direction (e.g., in the Y-direction). In some embodiments, the second conductive contact structures 154 are arranged such that between pairs of the second conductive contact structures 154 horizontally neighboring one another in a first direction (e.g., in the Y-direction), there are no horizontally intervening (e.g., in the Y-direction) first conductive contact structures 136. Similarly, the first conductive contact structures 136 are arranged such that there are no horizontally intervening (e.g., in the Y-direction) second conductive contact structures 154 between horizontally neighboring (e.g., in the Y-direction) first conductive contact structures 136.

The second conductive contact structures 154 may individually be horizontally offset from the first conductive contact structures 136 in each of a first horizontal direction (e.g., in the X-direction) and a second horizontal direction (e.g., in the Y-direction). The second conductive contact structures 154 may individually be located outside of horizontal boundaries of the first conductive contact structures 136 in the first horizontal direction and in the second horizontal direction such that horizontal boundaries of the second conductive contact structures 154 do not overlap with the horizontal boundaries of the first conductive contact structures 136. In other embodiments, the horizontal boundaries of the second conductive contact structures 154 in the first horizontal direction (e.g., in the X-direction) overlap with the horizontal boundaries of the first conductive contact structures 136.

The second conductive contact structures 154 may individually be formed of and include conductive material, such as one or more of the materials described above with reference to the conductive material 118 of the conductive structures 122. In some embodiments, the second conductive contact structures 154 individually comprise substantially the same material composition as the first conductive contact structures 136. In some embodiments, the second conductive contact structures 154 individually comprise tungsten.

After forming the second conductive contact structures 154, the microelectronic device structure assembly 150 may be exposed to, for example, a CMP process to substantially planarize a vertically uppermost (e.g., in the Z-direction) surface of the eighth insulative material 152. Vertically uppermost (e.g., in the Z-direction) surfaces of the second conductive contact structures 154 may be exposed through the eighth insulative material 152.

FIG. 1P is a simplified, partial cross-sectional view of the microelectronic device structure assembly 150 at a processing stage subsequent to that illustrated in FIG. 1N and FIG. 1O. The cross-sectional view illustrated in FIG. 1P is taken through the same plane of the microelectronic device structure assembly 150 illustrated in FIG. 1O, except at a subsequent processing stage of the microelectronic device structure assembly 150.

With reference to FIG. 1P, a stack structure 156 comprising a vertically alternating (e.g., in the Z-direction) sequence of insulative structures 158 and sacrificial structures 160. The vertically alternating sequence of insulative structures 158 and sacrificial structures 160 may be arranged in pairs, each pair comprising an insulative structure 158 and a sacrificial structure vertically neighboring (e.g., in the Z-direction) the insulative structure 158. In some embodiments, one of the sacrificial structures 160 vertically overlies (e.g., in the Z-direction) and directly contacts the eighth insulative material 152 and the second conductive contact structures 154.

The insulative structures 158 may be formed of and include insulative material, such as one or more of the materials described above with reference to the first insulative material 103. In some embodiments, the insulative structures 158 comprise silicon dioxide.

The sacrificial structures 160 may be formed of and include a material at least one material (e.g., at least one insulative material) that may be selectively removed relative to the insulative structures 158. The sacrificial structures 160 may be selectively etchable relative to the insulative structures 158 during common (e.g., collective, mutual) exposure to a first etchant; and the insulative structures 158 may be selectively etchable to the sacrificial structures 160 during common exposure to a second, different etchant. By way of non-limiting example, depending on the material composition of the insulative structures 158, the sacrificial structures 160 may be formed of and include one or more of at least one dielectric oxide material (e.g., one or more of AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H_{z}), at least one dielectric carboxynitride material (e.g., SiOₓC_{z}N_{y}), and at least one semiconductive material (e.g., polycrystalline silicon). In some embodiments, the sacrificial structures 160 individually comprise a dielectric nitride material, such as SiN_{y} (e.g., Si₃N₄). The sacrificial structures 160 may, for example, be selectively etchable relative to the insulative structures 158 during common exposure to a wet etchant comprising phosphoric acid (H₃PO₄).

FIG. 1Q is a simplified, partial top-down view of the microelectronic device structure assembly 150 at a processing stage subsequent to that illustrated in FIG. 1P. FIG. 1R is a partial, simplified cross-sectional view of the microelectronic device structure assembly 150 taken through section line R-R of FIG. 1Q. FIG. 1Q illustrates portions of the microelectronic device structure assembly 150 vertically below (e.g., in the Z-direction) a vertically uppermost (e.g., in the Z-direction) surface of the microelectronic device structure assembly 150 to illustrate the relative horizontal locations of different components of the microelectronic device structure assembly 150.

With reference to FIG. 1Q and FIG. 1R, third trenches 162 may be formed within the stack structure 156 and directly vertically over (e.g., in the Z-direction) the first trenches 107 comprising the sixth insulative material 132. In some embodiments, the third trenches 162 horizontally extend (e.g., in the Y-direction) beyond horizontal boundaries of the first trenches 107. In some embodiments, the first trenches 107 are located within horizontal boundaries (e.g., in the Y-direction) of the third trenches 162.

With reference to FIG. 1Q, in some embodiments, fourth trenches 164 may be formed within the stack structure 156 and horizontally extending in a horizontal direction (e.g., in the X-direction) substantially perpendicular to the horizontal direction in which the third trenches 162 horizontally extend. In some embodiments, the fourth trenches 164 vertically overlie (e.g., in the Z-direction) and be located within horizontal boundaries (e.g., in the X-direction) the first insulative material 103 (FIG. 1N).

The third trenches 162 and the fourth trenches 164 may individually be formed by, for example, sequentially removing portions of the insulative structures 158 and the sacrificial structures 160 through, for example, a mask material. The portions of the insulative structures 158 and the sacrificial structures 160 may be removed by exposing the insulative structures 158 and the sacrificial structures 160 to one or more dry etchants, such as one or more of CF₄ (e.g., a mixture of CF₄, O2, and N₂), CHF₃, CCl₂F₂, NF₃ (e.g., a mixture of NF₃ and O₂), and SF₆.

The third trenches 162 and the fourth trenches 164 may individually be filled with a ninth insulative material 166. The ninth insulative material 166 may be formed of and include insulative material, such as one or more of the materials described above with reference to the first insulative material 103. In some embodiments, the ninth insulative material 166 comprises substantially the same material composition as the insulative structures 158. In some embodiments, the ninth insulative material 166 comprises silicon dioxide.

FIG. 1S is a simplified, partial top-down view of the microelectronic device structure assembly 150 at a processing stage subsequent to that illustrated in FIG. 1Q and FIG. 1R. FIG. 1T is a partial, simplified cross-sectional view of the microelectronic device structure assembly 150 taken through section line T-T of FIG. 1S. FIG. 1S illustrates portions of the microelectronic device structure assembly 150 vertically below (e.g., in the Z-direction) a vertically uppermost (e.g., in the Z-direction) surface of the microelectronic device structure assembly 150 to illustrate the relative horizontal locations of different components of the microelectronic device structure assembly 150.

With reference to FIG. 1S and FIG. 1T, fifth trenches 168 may be formed through the stack structure 156 vertically over (e.g., in the Z-direction) the second conductive contact structures 154 to expose vertically uppermost (e.g., in the Z-direction) surfaces of the second conductive contact structures 154. The fifth trenches 168 may be formed vertically over the second trenches 130 (FIG. 1Q). In some embodiments, the second trenches 130 and a pair of second conductive contact structures 154 spaced from one another by a second trench 130 are located within horizontal boundaries (e.g., in the Y-direction) of the fifth trenches 168.

The fifth trenches 168 may be formed by sequentially removing portions of the insulative structures 158 and the sacrificial structures 160, as described above with reference to formation of the third trenches 162 and the fourth trenches 164. For clarity and case of understanding the description, vertically uppermost (e.g., in the Z-direction) surfaces of the structures and materials exposed by the fifth trenches 168 (e.g., the eighth insulative material 152 and the second conductive contact structures 154) are not illustrated in FIG. 1S.

FIG. 1U is a simplified, partial cross-sectional view of the microelectronic device structure assembly 150 at a processing stage subsequent to that illustrated in FIG. 1R and FIG. 1S. After forming the fifth trenches 168, the sacrificial structures 160 (FIG. 1T) may be selectively removed relative to the insulative structures 158, the eighth insulative material 152, and the second conductive contact structures 154. Selective removal of the sacrificial structures 160 may expose horizontally extending portions (e.g., in the X-direction, in the Y-direction) portions of the insulative structures 158 and vertically extending portions (e.g., in the Z-direction) of the ninth insulative material 166.

By way of non-limiting example, the sacrificial structures 160 (FIG. 1T) may be selectively removed relative to the insulative structures 158, the eighth insulative material 152, and the second conductive contact structures 154 by exposing the sacrificial structures 160 to a wet etchant, such as phosphoric acid.

With continued reference to FIG. 1U, after selectively removing the sacrificial structures 160 (FIG. 1T), a first electrode material 170 may be formed on surfaces of the insulative structures 158 and the ninth insulative material 166. The first electrode material 170 may be in contact with and configured to be in electrical communication with the second conductive contact structures 154. In some embodiments, the first electrode material 170 is formed by deposition, such as by ALD.

The first electrode material 170 may be formed of and include conductive material such as, for example, one or more of a metal (e.g., tungsten, titanium, nickel, platinum, rhodium, ruthenium, aluminum, copper, molybdenum, iridium, silver, gold), a metal alloy, a metal-containing material (e.g., metal nitrides, metal silicides, metal carbides, metal oxides), a material including at least one of titanium nitride (TiN), tantalum nitride (TaN), tungsten nitride (WN), titanium aluminum nitride (TiAlN), iridium oxide (IrOₓ), ruthenium oxide (RuOₓ), alloys thereof, a conductively doped semiconductor material (e.g., conductively doped silicon, conductively doped germanium, conductively doped silicon germanium), polysilicon, and other materials exhibiting electrical conductivity. In some embodiments, the first electrode material 170 comprises titanium nitride.

FIG. 1V is a simplified, partial cross-sectional view of the microelectronic device structure assembly 150 at a processing stage subsequent to that illustrated in FIG. 1U. After forming the first electrode material 170, a dielectric material 172 may be formed on surfaces of the first electrode material 170. In some embodiments, the dielectric material 172 is formed by deposition, such as by ALD. After forming the dielectric material 172, a second electrode material 174 may be formed over the dielectric material 172.

The dielectric material 172 may be formed of and include one or more of silicon dioxide (SiO₂), silicon nitride (Si₃N₄), polyimide, titanium dioxide (TiO₂), tantalum oxide (Ta₂O₅), aluminum oxide (Al₂O₃), an oxide-nitride-oxide material (e.g., silicon dioxide-silicon nitride-silicon dioxide), strontium titanate (SrTiO₃) (STO), barium titanate (BaTiO₃), hafnium oxide (HfO₂), zirconium oxide (ZrO₂), a ferroelectric material (e.g., ferroelectric hafnium oxide, ferroelectric zirconium oxide, lead zirconate titanate (PZT)), and a high-k dielectric material.

The second electrode material 174 may be formed of and include conductive material, such as one or more of the materials described above with reference to the first electrode material 170. In some embodiments, the second electrode material 174 comprises substantially the same material composition as the first electrode material 170.

FIG. 1W is a simplified, partial top-down view of a microelectronic device 190 formed from the microelectronic device structure assembly 150 (FIG. 1V) at a processing stage subsequent to that illustrated in FIG. 1V. FIG. 1X is a simplified, partial cross-sectional view of the microelectronic device structure assembly 150 taken through section line X-X of FIG. 1W. FIG. 1Y is a simplified, partial cross-sectional view of the microelectronic device structure assembly 150 taken through section line Y-Y of FIG. 1W.

With collective reference to FIG. 1W through FIG. 1Y, after forming the second electrode material 174 horizontally extending portions (e.g., in the X-direction, in the Y-direction) of the second electrode material 174 may be removed (e.g., punched through) from the fifth trenches 168 and vertically underlying (e.g., in the Z-direction) portions of the dielectric material 172 and the first electrode material 170 may be removed to expose portions of the eighth insulative material 152 (e.g., at locations corresponding to the location of the second trenches 130). In some embodiments, portions of the first electrode material 170 are such that a first electrode material 170 in contact with a second conductive contact structure 154 is not in contact with a second conductive contact structure 154. In other words, removal of the portions of the first electrode material 170 may electrically isolate the second conductive contact structures 154 from one another.

Referring to FIG. 1X and FIG. 1Y, a tenth insulative material 180 may be formed vertically over (e.g., in the Z-direction) the microelectronic device structure assembly 150 and over surfaces of the second electrode material 174 within the fifth trenches 168.

Removal of the portions of the first electrode material 170, the dielectric material 172, and the second electrode material 174 forms electrically isolated storage devices 176 each individually comprising the first electrode material 170, the second electrode material 174, and the dielectric material 172 between the first electrode material 170 and the second electrode material 174. Accordingly, each of the storage devices 176 individually comprises a first electrode material 170 (also referred to herein as “a first electrode,” “an outer electrode,” “a first electrode plate,” or a “first node structure”), a second electrode material 174 (also referred to herein as “a second electrode,” “an inner electrode,” “a second electrode plate,” or a “second node structure”), and a dielectric material 172 between the first electrode 170 and the second electrode 174. In some such embodiments, the storage devices 176 individually comprise capacitors. However, the disclosure is not so limited and in other embodiments, the storage devices 176 may each individually comprise other structures, such as, for example, phase change memory (PCM), resistance random-access memory (RRAM), conductive-bridging random-access memory (conductive bridging RAM), or another structure for storing a logic state.

Each of the storage devices 176 may comprise multiple vertical levels (e.g., in the Z-direction) of the first electrode material 170, the dielectric material 172, and the second electrode material 174. The quantity of the vertical levels of the first electrode material 170, the dielectric material 172, and the second electrode material 174 may correspond to the number of levels of the sacrificial structures 160 of the stack structure 156 (FIG. 1S). Although FIG. 1X and FIG. 1Y illustrate that the storage devices 176 include five (5) levels of the first electrode material 170, the dielectric material 172, and the second electrode material 174, the disclosure is not so limited. In other embodiments, the storage devices 176 include a greater quantity (e.g., greater than six (6), greater than eight (8), greater than twelve (12), greater than twenty (20)) levels of the first electrode material 170, the dielectric material 172, and the second electrode material 174. In yet other embodiments, the storage devices 176 include fewer (e.g., four (4), three (3), two (2)) levels of the first electrode material 170, the dielectric material 172, and the second electrode material 174. A quantity of the levels of the first electrode material 170, the dielectric material 172, and the second electrode material 174 may be determined based on a desired capacitance of the storage devices 176.

In some embodiments, each of the storage devices 176 includes horizontally extending (e.g., in the X-direction, in the Y-direction) first electrode materials 170 that are vertically spaced (e.g., in the Z-direction) from one another by, for example, horizontally extending (e.g., in the X-direction, in the Y-direction) of the dielectric material 172, the second electrode material 174, and the ninth insulative material 166. In addition, each of the storage devices 176 includes horizontally extending (e.g., in the X-direction, in the Y-direction) second electrode materials 174 that are vertically spaced (e.g., in the Z-direction) from one another by, for example, horizontally extending (e.g., in the X-direction, in the Y-direction) portions of the first electrode material 170, dielectric material 172, and the ninth insulative material 166.

Formation of the storage devices 176 may form memory cells 182, each individually comprising transistor structures 125 from the stack structure 135 and a storage device 176 from the stack structure 156 and vertically overlying (e.g., in the Z-direction) the transistor structures 125. Two of the memory cells 182 are illustrated in dashed boxes 182 in FIG. 1W through FIG. 1Y.

For clarity and case of understanding the description, the storage devices 176 are not illustrated in the view of FIG. 1W. However, it will be understood that the storage devices 176 (FIG. 1X, FIG. 1Y) are individually located within an area between horizontally neighboring (e.g., in the X-direction) fourth trenches 164 and between horizontally neighboring (e.g., in the Y-direction) third trenches 162 and a horizontally neighboring fifth trench 168. The active area (e.g., the first material 104 including the channel regions 127) of each memory cell 182 may be within the boundaries defined by the box 182.

Each of the memory cells 182 may include multiple (e.g., two or more, such as two) of the transistor structures 125. In some embodiments, each of the memory cells 182 comprises two of the transistor structures 125 in operable communication with (e.g., electrical communication with) a storage device 176. In some such embodiments, the memory cells 182 may be referred to as so-called two transistor-one capacitor (2T-1C) memory cells. The transistor structures 125 of a single memory cell 182 may be vertically stacked (e.g., in the Z-direction) with respect to one another. By way of non-limiting example, the memory cells 182 may individually comprise two transistor structures 125 vertically spaced (e.g., in the Z-direction) from one another. A first one of the transistor structures 125 may be closer to the storage device 176 than a second one of the transistor structure 125; and the second one of the transistor structure 125 may be closer to the conductive line 138 than the first one of the transistor structures 125.

In some embodiments, a vertical height (e.g., in the Z-direction) H₁ of the storage device 176 of a memory cell 182 is greater than a vertical height (e.g., in the Z-direction) H₂ of the transistor structures 125 of the memory cell 182. In some embodiments, a vertical height of the stack structure 156 is greater than a vertical height of the stack structure 135.

With combined reference to FIG. 1W through FIG. 1Y, a vertical height (e.g., in the Z-direction) of each individual memory cell 182 may be greater horizontal dimensions (e.g., in the X-direction, in the Y-direction) of the individual memory cell 182.

The transistor structures 125 of a particular memory cell 182 are in contact with a second conductive contact structure 154 that is configured to electrically connect the transistor structures 125 to the storage device 176, such as to the first electrode material 170 of the storage device 176. In some such embodiments, the transistor structures 125 are individually in electrical communication with the storage device 176. In addition, the transistor structures 125 of the memory cell 182 are in electrical communication with the conductive line 138 by means of the conductive material 126 and the first conductive contact structures 136 (FIG. 1Y). Since the second conductive contact structures 154 are configured to electrically connect the transistor structures 125 to the storage device 176, the second conductive contact structures 154 may be referred to herein as “cell contact structures” or “memory cell contact structures.”

In some embodiments, the transistor structures 125 of a particular memory cell 182 vertically intervene (e.g., in the Z-direction) between the conductive line 138 and the storage device 176 of the memory cell 182. In other embodiments, the conductive line 138 vertically intervenes (e.g., in the Z-direction) between the transistor structures 125 and the storage device 176.

With continued reference to FIG. 1X and FIG. 1Y, after forming the tenth insulative material 180, additional openings may be formed in the tenth insulative material 180 to expose portions (e.g., vertically uppermost (e.g., in the Z-direction)) surfaces of the second electrode material 174 of the storage devices 176 and filled with a conductive material 184. The conductive material 184 may be in contact with and in electrical communication with the second electrode material 174 of the storage devices 176. The conductive material 184 may also be referred to herein as a “conductive plate” or a “capacitor plate.”

The conductive material 184 may be formed of and include conductive material, such as one or more of the materials described above with reference to the conductive material 118 of the conductive structures 122. In some embodiments, the conductive material 184 comprises tungsten.

The tenth insulative material 180 may be formed of and include insulative material, such as one or more of the materials described above with reference to the first insulative material 103. In some embodiments, the tenth insulative material 180 comprises silicon dioxide.

With continued reference to FIG. 1X and FIG. 1Y, after forming the memory cells 182, the tenth insulative material 180, and the conductive material 184, the second base structure 144 (FIG. 1V) may be removed from the microelectronic device structure assembly 150 to form the microelectronic device 190 comprising the memory cells 182. The second base structure 144 may be removed using conventional removal processes (e.g., conventional detachment processes, conventional grinding processes) and conventional equipment, which are also not described in detail herein.

Forming the microelectronic device 190 to include memory cells 182 comprising multiple (e.g., two) transistor structures 125 vertically spaced (e.g., in the Z-direction) from one another may facilitate forming the memory cells 182 to exhibit a reduced read disturb compared to conventional microelectronic devices including 1T-1C memory cells, without increasing a horizontal area (e.g., in the X-direction, in the Y-direction) occupied by the memory cells 182. In addition, forming the storage devices 176 vertically over (e.g., in the Z-direction) the transistor structures 125 facilitates forming the storage devices 176 to exhibit a desired capacitance, which may be based at least in part, on the quantity of levels (and, thus, the height) of the storage devices 176. Accordingly, the capacitance of the storage devices 176 may be increased or decreased by respectively increasing or decreasing the number of levels of the first electrode material 170, the dielectric material 172, and the second electrode material 174 defining the storage devices 176. Accordingly, the capacitance of the storage devices 176 may be increased or decreased without increasing or decreasing the horizontal area occupied by the storage devices 176, and thus, the memory cells 182. In addition, because the memory cells 182 comprise 2T-1C memory cells, read operations of the memory cells 182 may not require sensing a reference voltage of a sense amplifier (e.g., a DVC2 sense amplifier reference voltage), reducing the processing and operating cost of the memory cells 182. In some embodiments, the memory cells 182 may be configured to provide an equivalent read signal compared to a conventional 1T-1C memory cell, but with a lower capacitance (e.g., of the storage device 176).

In some embodiments, the memory cells 182 described herein may exhibit a reduced write recovery time compared to memory cells comprising a single transistor and a single storage device; or compared to memory cells including storage devices exhibiting a relatively lower capacitance. The memory cells 182 described herein may exhibit up to three times the signal (e.g., a read voltage) compared to memory cells comprising a single transistor.

Although FIG. 1A through FIG. 1Y have been described and illustrated as forming the microelectronic device 190 to include the transistor structures 125 vertically between (e.g., in the Z-direction) the conductive lines 138 and the storage devices 176, the disclosure is not so limited. For example, rather than attaching the microelectronic device structure 100 to a carrier wafer 142 and vertically flipping (e.g., in the Z-direction) the microelectronic device structure 100 prior to formation of the second conductive contact structures 154, the microelectronic device structure 100 may not be attached to a carrier wafer and vertically flipped.

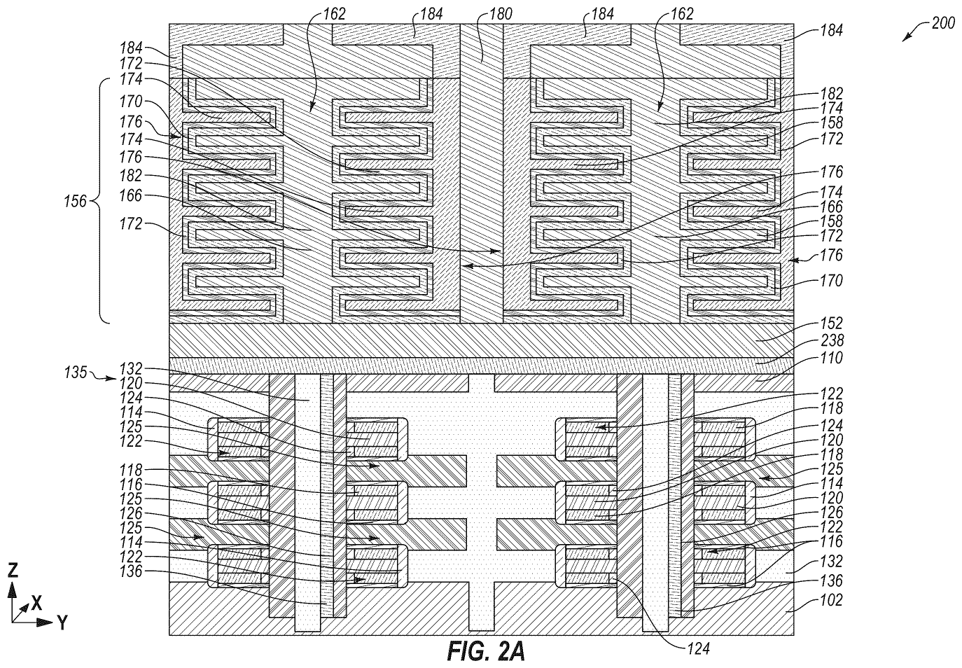

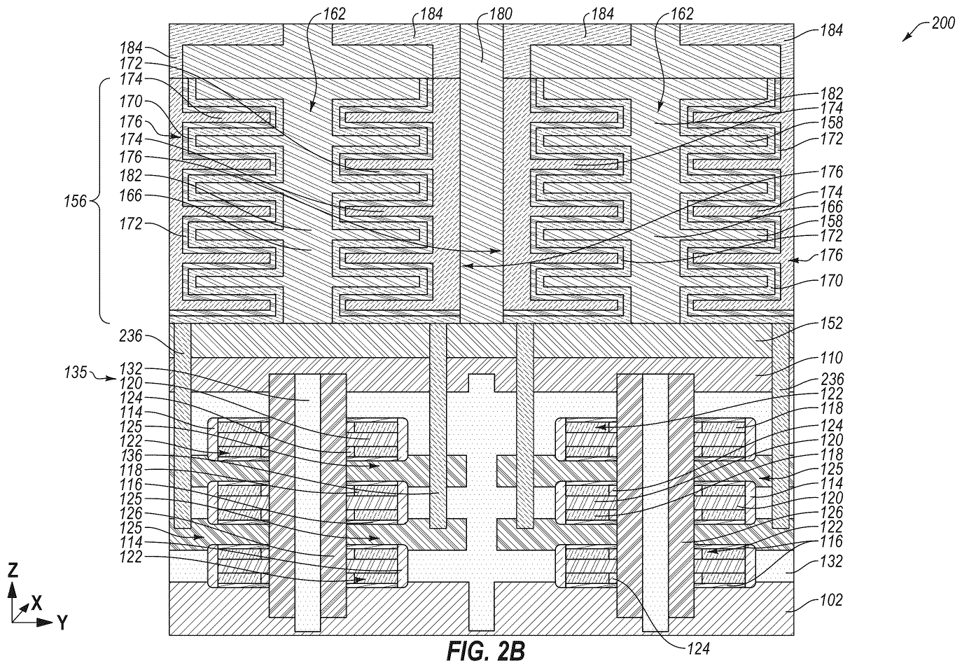

FIG. 2A and FIG. 2B are simplified, partial cross-sectional views of a microelectronic device 200, in accordance with embodiments of the disclosure. FIG. 2A is a simplified, partial cross-sectional view of the microelectronic device 200 illustrating a cross-section through the first conductive contact structures 136, similar to the cross-sectional view of the microelectronic device 190 of FIG. 1Y. FIG. 2B is a simplified, partial cross-sectional view of the microelectronic device 200 illustrating a cross-section through the second conductive contact structures 154, similar to the cross-sectional view of the microelectronic device 190 of FIG. 1X.

With reference to FIG. 2A and FIG. 2B, the microelectronic device 200 may be substantially the same as the microelectronic device 190 of FIG. 1V through FIG. 1X, except that the microelectronic device 200 includes the conductive lines 238 vertically between (e.g., in the Z-direction) transistor structures 125 and the storage devices 176. The conductive lines 238 may be substantially similar to the conductive lines 138 of the microelectronic device 190, except that the conductive lines 238 vertically intervene (e.g., in the Z-direction) between the transistor structures 125 and the storage devices 176.

Thus, in accordance with some embodiments of the disclosure, a microelectronic device comprises a first transistor structure, a second transistor structure vertically overlying the first transistor structure, a storage device vertically overlying the second transistor structure, a first conductive contact structure contacting the first transistor structure, the second transistor structure, and a first electrode of the storage device, and a second conductive contact structure configured to be in electrical communication with the first transistor structure and the second transistor structure.

Thus, in accordance with some embodiments of the disclosure, a memory device comprises an array of memory cells, each memory cell of the array of memory cells comprising a first transistor vertically spaced from a second transistor and a capacitor vertically overlying the first transistor and the second transistor. The capacitor comprises a first electrode material, a second electrode material, and a dielectric material between the first electrode material and the second electrode material, wherein the first electrode material, the second electrode material, and the dielectric material individually comprise vertical levels spaced from one another by levels of insulative material. The memory device further comprises a conductive contact structure in contact with the first transistor, the second transistor, and the first electrode.

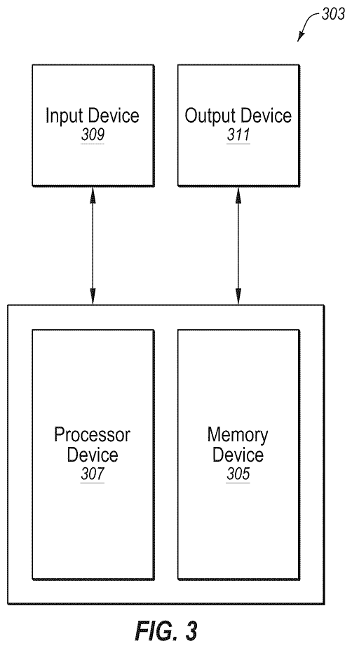

Microelectronic devices (e.g., the microelectronic device 190, 200) of the disclosure may be included in embodiments of electronic systems of the disclosure. For example, FIG. 3 is a block diagram of an electronic system 303, in accordance with embodiments of the disclosure. The electronic system 303 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 303 includes at least one memory device 305. The memory device 305 may include, for example, an embodiment of a microelectronic device previously described herein (e.g., the microelectronic device 190, 200 previously described with reference to FIG. 1V through FIG. 1X and FIG. 2).

The electronic system 303 may further include at least one electronic signal processor device 307 (often referred to as a “microprocessor”). The electronic signal processor device 307 may, optionally, include an embodiment of one or more of a microelectronic device and a microelectronic device structure previously described herein. The electronic system 303 may further include one or more input devices 309 for inputting information into the electronic system 303 by a user, such as, for example, a mouse or other pointing device, a keyboard, a touchpad, a button, or a control panel. The electronic system 303 may further include one or more output devices 311 for outputting information (e.g., visual or audio output) to a user such as, for example, a monitor, a display, a printer, an audio output jack, a speaker, etc. In some embodiments, the input device 309 and the output device 311 may comprise a single touchscreen device that can be used both to input information to the electronic system 303 and to output visual information to a user. The input device 309 and the output device 311 may communicate electrically with one or more of the memory device 305 and the electronic signal processor device 307.

Accordingly, in at least some embodiments, an electronic device comprises an input device, an output device, a processor device operably coupled to the input device and the output device, and a memory device operably coupled to the processor device and comprising at least one microelectronic device structure. The at least one microelectronic device structure comprises a vertical stack of transistors comprising vertical pairs of transistors, the transistors of each of the vertical pairs of transistors vertically spaced from one another, and a stack structure comprising capacitors vertically overlying the vertical stack of transistors, each of the capacitors configured to be in electrical communication with a respective vertical pair of the transistors to form a memory cell, the stack structure having a greater thickness in a vertical direction than the vertical stack of transistors.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. A microelectronic device, comprising:
a first transistor structure;
a second transistor structure vertically overlying the first transistor structure;
a storage device vertically overlying the second transistor structure;
a first conductive contact structure contacting the first transistor structure, the second transistor structure, and a first electrode of the storage device; and
a second conductive contact structure configured to be in electrical communication with the first transistor structure and the second transistor structure.

2. The microelectronic device of claim 1, further comprising a conductive line coupled to the second conductive contact structure.

3. The microelectronic device of claim 2, wherein the conductive line is vertically separated from the storage device by the first transistor structure and the second transistor structure.

4. The microelectronic device of claim 2, wherein the conductive line is vertically between the first transistor structure and the storage device.

5. The microelectronic device of claim 1, wherein the first conductive contact structure vertically extends through the first transistor structure and the second transistor structure.

6. The microelectronic device of claim 1, wherein a vertical height of the storage device is greater than a vertical height of the first transistor structure and the second transistor structure.

7. The microelectronic device of claim 1, wherein the second transistor structure is located within horizontal boundaries of the first transistor structure.

8. The microelectronic device of claim 1, wherein the storage device comprises:
first vertically spaced portions of a first electrode material; and
vertically spaced portions of a second electrode material.

9. The microelectronic device of claim 1, wherein the first conductive contact structure is horizontally offset from the second conductive contact structure in a first horizontal direction and a second horizontal direction.

10. A memory device, comprising:
an array of memory cells, each memory cell of the array of memory cells comprising:
a first transistor vertically spaced from a second transistor;
a capacitor vertically overlying the first transistor and the second transistor, the capacitor comprising:
a first electrode material;
a second electrode material; and
a dielectric material between the first electrode material and the second electrode material, wherein the first electrode material, the second electrode material, and the dielectric material individually comprise vertical levels spaced from one another by levels of insulative material; and
a conductive contact structure in contact with the first transistor, the second transistor, and the first electrode.

11. The memory device of claim 10, further comprising second conductive contact structures, each of the second conductive contact structures vertically extending adjacent to the first transistor and the second transistor of a memory cell and configured to be in electrical communication with the first transistor and the second transistor.

12. The memory device of claim 11, wherein at least one of the second conductive contact structures is horizontally offset, in a first horizontal direction and a second horizontal direction, from at least one other of the second conductive contact structures most proximate thereto.

13. The memory device of claim 10, wherein the first transistor and the second transistor are individually located within horizontal boundaries of the capacitor.

14. The memory device of claim 10, further comprising a conductive line configured to be in electrical communication with the first transistor and the second transistor, the conductive line vertically spaced from the capacitor by the first transistor and the second transistor.

15. The memory device of claim 10, wherein the first transistor and the second transistor individually comprise gate-all-around (GAA) transistors.

16. An electronic system, comprising:
an input device;
an output device;
a processor device operably coupled to the input device and the output device; and
a memory device operably coupled to the processor device and comprising at least one microelectronic device, the at least one microelectronic device comprising:
a vertical stack of transistors comprising vertical pairs of transistors, the transistors of each of the vertical pairs of transistors vertically spaced from one another; and
a stack structure comprising capacitors vertically overlying the vertical stack of transistors, each of the capacitors configured to be in electrical communication with a respective vertical pair of the transistors to form a memory cell, the stack structure having a greater thickness in a vertical direction than the vertical stack of transistors.

17. The electronic system of claim 16, wherein the capacitors individually comprise vertically spaced portions of a first electrode material.

18. The electronic system of claim 16, wherein a bottom electrode of each of the capacitors is in electrical communication with the vertical pair of transistor vertically underlying the capacitor.

19. The electronic system of claim 16, further comprising conductive contact structures in contact with a conductive line vertically underlying the vertical stack of transistors and configured to electrically connect the transistors to the conductive line.

20. The electronic system of claim 16, wherein a vertical dimension of the memory cell is greater than a horizontal dimension of the memory cell.
